(19) United States
(12) Patent Application Publication
(10) Pub. No.: US 2020/0024150 A1
(43) Pub. Date: Jan. 23, 2020

(54) TIME-DEPENDENT ELEMENT, PHYSICAL PROPERTY TEMPORAL CHANGE PREDICTION DEVICE, AND ELECTRIC CIRCUIT BREAKER

(71) Applicant: PANASONIC INTELLECTUAL PROPERTY MANAGEMENT CO., LTD., Osaka (JP)

(72) Inventors: Yoshitaka NAKAMURA, Osaka (JP); Tsutomu FURUTA, Hyogo (JP); Hiroyoshi YODEN, Osaka (JP)

(73) Assignee: PANASONIC INTELLECTUAL PROPERTY MANAGEMENT CO., LTD., Osaka (JP)

(21) Appl. No.: 16/499,794

(22) PCT Filed: Mar. 20, 2018
(86) PCT No.: PCT/JP2018/011014

§ 371 Date: Sep. 30, 2019

(30) Foreign Application Priority Data
Mar. 30, 2017 (JP) 2017-068232

(51) Int. Cl. C01G 23/04; C04B 35/46; H01H 71/00; H01L 45/00

(52) U.S. Cl. CPC C01G 23/04; H01L 45/147; H01H 71/00; C04B 35/46

(57) ABSTRACT

A time-dependent element of the present invention includes a time-dependent phase transition material that undergoes solid-solid phase transition developing with time after production irrespective of the presence of an external stimulus, in which one or more physical properties of the time-dependent element selected from a group consisting of composition, volume, transmittance, reflectance, electric resistance, and magnetic property change with time. A physical property temporal change prediction device includes a physical property temporal change prediction device body having the time-dependent element and is configured to predict a temporal change in one or more physical properties selected from a group consisting of composition, volume, transmittance, reflectance, electric resistance, and magnetic property.

### TECHNICAL FIELD

The present invention relates to a time-dependent element that undergoes solid-solid phase transition developing with time after production irrespective of the presence of external stimuli and changes in physical properties with time, and a physical property temporal change prediction device and an electric circuit breaker that include the time-dependent element.

### BACKGROUND ART

Elements and devices utilizing electric and magnetic changes of materials that undergo phase transition have been developed and used in memories and switches.

For example, Patent Literature 1 discloses a switching element using a perovskite-type manganese oxide material that is expressed by Pr_{0.7}Ca_{0.3}MnO₃ and undergoes phase transition between antiferromagnetic insulator and ferromagnetic metal due to current, electric field, or the like. Patent Literature 2 discloses a magneto-optical recording medium that uses a magnetic phase transition material that undergoes phase transition from antiferromagnetic to ferromagnetic properties at a temperature T₁ when the temperature is rising and undergoes phase transition from ferromagnetic to antiferromagnetic properties at a temperature T₂ when the temperature is falling.

### CITATION LIST

### Patent Literature

Patent Literature 1: Japanese Patent Publication No. 3030333

Patent Literature 2: Japanese Unexamined Patent Application Publication No. 9-231629

### SUMMARY OF INVENTION

### Problems to be Solved by Invention

However, the materials that undergo phase transition and are described in Patent Literatures 1 and 2 need to be supplied with power or energy to cause phase transition, including electricity, magnetism, or heat. Elements that use the aforementioned materials that undergo phase transition cannot be used when there is no power.

The present invention was made in the light of the aforementioned issue. An object of the present invention is to provide a time-dependent element including a material that undergoes phase transition developing with time without supply of any power or energy. Another object of the present invention is to provide a physical property temporal change prediction device that uses the time-dependent element to predict a temporal change in physical properties with time and an electric circuit breaker using the physical property temporal change prediction device.

### Solution to Problem

To solve the aforementioned issues, a time-dependent element according to a first aspect of the present invention includes a time-dependent phase transition material that undergoes solid-solid phase transition developing with time after production irrespective of the presence of an external stimulus, in which one or more physical properties of the time-dependent element selected from a group consisting of composition, volume, transmittance, reflectance, electric resistance, and magnetic property change with time.

A physical property temporal change prediction device according to a second aspect of the present invention includes a physical property temporal change prediction device body having the time-dependent element and is configured to predict a temporal change in one or more physical properties selected from a group consisting of composition, volume, transmittance, reflectance, electric resistance, and magnetic property.

An electric circuit breaker according to a third aspect of the present invention includes the physical property temporal change prediction device and is configured to predict a temporal change in the electric resistance.

An electric circuit breaker according to a fourth aspect of the present invention includes the physical property temporal change prediction device and is configured to predict a temporal change in the volume.

### BRIEF DESCRIPTION OF DRAWINGS

FIG. 1 is a schematic perspective view illustrating a physical property temporal change prediction device according to a first embodiment.

FIG. 2 is a schematic perspective view illustrating a physical property temporal change prediction device according to a second embodiment.

FIG. 3A is a schematic perspective view illustrating a physical property temporal change prediction device according to a third embodiment. FIG. 3B is a schematic cross-sectional view along a line C-C of FIG. 3A.

FIG. 4A is a schematic perspective view illustrating a physical property temporal change prediction device according to a fourth embodiment. FIG. 4B is a schematic cross-sectional view along a line D-D of FIG. 4A.

FIG. 5A is a schematic perspective view illustrating a physical property temporal change prediction device according to a fifth embodiment. FIG. 5B is a schematic cross-sectional view along a line E-E of FIG. 5A.

FIG. 6A is a schematic perspective view illustrating a physical property temporal change prediction device according to a sixth embodiment. FIG. 6B is a schematic cross-sectional view along a line F-F of FIG. 6A.

FIG. 7A is a schematic perspective view illustrating a physical property temporal change prediction device according to a seventh embodiment. FIG. 7B is a schematic cross-sectional view along a line G-G of FIG. 7A.

FIG. 8A is a schematic perspective view illustrating a physical property temporal change prediction device according to an eighth embodiment. FIG. 8B is a schematic cross-sectional view along a line H-H of FIG. 8A.

FIG. 9 is a schematic perspective view illustrating a physical property temporal change prediction device according to a ninth embodiment.

FIG. 10 is a schematic perspective view illustrating a physical property temporal change prediction device according to a 10th embodiment.

FIG. 11 is a schematic cross-sectional view illustrating a physical property temporal change prediction device according to an 11th embodiment.

FIG. 12 is a schematic cross-sectional view illustrating a physical property temporal change prediction device according to a 12th embodiment.

FIG. 13 is a schematic perspective view illustrating a physical property temporal change prediction device according to a 13th embodiment.

FIG. 14 is a diagram illustrating X-ray diffraction analysis results.

FIG. 15 is a graph illustrating the relationship between the number of days that have elapsed since production of a time-dependent phase transition material and the phase ratio (λ-phase content) of λ-Ti₃O₅ in the time-dependent phase transition material and the phase ratio β-phase content) of β-Ti₃O₅.

### DESCRIPTION OF EMBODIMENTS

Hereinafter, a description is given of physical property temporal change prediction devices according to embodiments with reference to the drawings.

### [Physical Property Temporal Change Prediction Device]

### First Embodiment

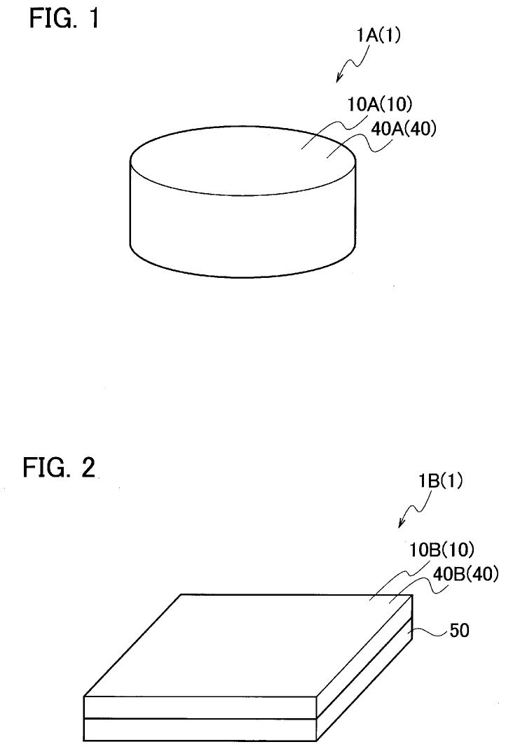

FIG. 1 is a schematic perspective view illustrating a physical property temporal change prediction device according to a first embodiment. A physical property temporal change prediction device 1A (1) illustrated in FIG. 1 includes a physical property temporal change prediction device body 10A (10). The physical property temporal change prediction device 1A needs to include at least the physical property temporal change prediction device body 10A illustrated in FIG. 1 and may further include not-illustrated peripheral members. Physical property temporal change prediction devices 1B to 1M according to second to 13th embodiments described later include physical property temporal change prediction device bodies 10B to 10M, respectively, in a similar manner to the physical property temporal change prediction device 1A according to the first embodiment.

### <Physical Property Temporal Change Prediction Device Body>

The physical property temporal change prediction device body 10 is a member including a time-dependent element 40. The physical property temporal change prediction device body 10A (10) illustrated in FIG. 1 is composed of the time-dependent element 40A (40) and substantially does not include any material other than the time-dependent element 40A. In the later-described physical property temporal change prediction device 1C according to the third embodiment, for example, the physical property temporal change prediction device 10 includes a base material 30, which is a material other than the time-dependent element 40.

### [Time-Dependent Element]

The time-dependent element 40 denotes an element that includes a time-dependent phase transition material and changes in a particular physical property with time. Herein, the particular physical property denotes one or more physical properties selected from a group consisting of composition, volume, transmittance, reflectance, electric resistance, and magnetic property. Examples of the change in such a particular physical property with time are changes in composition, volume, color, electric resistance, and magnetic property. The change in color can be substituted with a change in transmittance or reflectance.

### (Time-Dependent Phase Transition Material)

The time-dependent element 40 illustrated in FIG. 1 is an element made of a time-dependent phase transition material. In other words, the time-dependent phase transition material is a material of the time-dependent element 40. Herein, the time-dependent phase transition material denotes a substance that undergoes solid-solid phase transition developing with time after production irrespective of the presence of external stimuli. Herein, “irrespective of the presence of external stimuli” means “irrespective of the presence of external supply of power or energy, including electricity, magnetism, or heat”.

The solid-solid phase transition means phase transition between solids having the same composition. The solid-solid phase transition does not include phase transition between liquid or gas and solid and changes between solid matters having different compositions. Examples of the solid-solid phase transition include phase transition between λ-phase trititanium pentoxide and β-phase trititanium pentoxide when the time-dependent phase transition material is trititanium pentoxide including crystal grains of at least one of λ-phase trititanium pentoxide and β-phase trititanium pentoxide. Trititanium pentoxide as the time-dependent phase transition material needs to include crystal grains of at least λ-phase trititanium pentoxide (λ-Ti₃O₅) immediately after production as described later. “To undergo phase transition” means that the aforementioned crystal grains of λ-phase trititanium pentoxide in the trititanium pentoxide undergo phase transition into crystal grains of β-phase trititanium pentoxide (β-Ti₃O₅).

The time-dependent phase transition material is an oxide, a pure metal, or an alloy, for example. Examples of the oxide include trititanium pentoxide (Ti₃O₅) including crystal grains of at least λ-phase trititanium pentoxide. The trititanium pentoxide functioning as the time-dependent phase transition material is referred to as “time-dependent phase transition trititanium pentoxide” hereinafter. The time-dependent phase transition trititanium pentoxide is preferred because solid-solid phase transition developing with time after production irrespective of the presence of external stimuli occurs pronouncedly among time-dependent phase transition materials.

The oxide may be a time-dependent phase transition trititanium pentoxide with a part of the composition thereof substituted with another element. For example, Ti in the time-dependent phase transition trititanium pentoxide may be substituted with Si, Mg, Al, Sc, V, Cr, Mn, Fe, Co, Ni, Cu, Zn, Y, Nb, Zr, or Hf. In addition, O in the time-dependent phase transition trititanium pentoxide may be substituted with H, N, or F. The time-dependent phase transition trititanium pentoxide may be subjected to both the substitution of Ti with the aforementioned elements and the substitution of O with the aforementioned elements. The values of suffixes of the oxide obtained by substituting Ti or O in Ti₃O₅ with another element can be properly changed. When the time-dependent phase transition trititanium pentoxide is an oxide obtained by substituting Ti or O in Ti₃O₅ with another element, phase transition temperature and phase transition pressure of the oxide can be either lower or higher than the phase transition temperature and phase transition pressure of Ti₃O₅, respectively.

The time-dependent phase transition trititanium pentoxide is described in detail. The time-dependent phase transition trititanium pentoxide includes crystal grains of at least λ-phase trititanium pentoxide immediately after production. The time-dependent phase transition trititanium pentoxide may include crystal grains of β-phase trititanium pentoxide in addition to crystal grains of λ-phase trititanium pentoxide. In the time-dependent phase transition trititanium pentoxide, β-phase trititanium pentoxide is stable while λ-phase trititanium pentoxide is metastable. The time-dependent phase transition trititanium pentoxide has a property that at least a portion of crystal grains of λ-phase trititanium pentoxide undergoes phase transition into crystal grains of β-phase trititanium pentoxide irrespective of the presence of external stimuli with time after production.

Even if composed of crystal grains of only λ-phase trititanium pentoxide immediately after production, the time-dependent phase transition trititanium pentoxide normally includes crystal grains of both λ-phase trititanium pentoxide and β-phase trititanium pentoxide thereafter. The phase ratio of λ-phase trititanium pentoxide to β-phase trititanium pentoxide in the time-dependent phase transition trititanium pentoxide used in the embodiments may have any value immediately after production.

The property of at least a portion of crystal grains of λ-phase trititanium pentoxide in the time-dependent phase transition trititanium pentoxide changing into crystal grains of β-phase trititanium pentoxide due to phase transition from λ-phase trititanium pentoxide to β-phase trititanium pentoxide normally develops at lower than 190° C. When the time-dependent phase transition trititanium pentoxide is at higher than 190° C., at least a portion of crystal grains of trititanium pentoxide undergoes phase transition into crystal grains of α-phase trititanium pentoxide, making difficult, phase transition from λ-phase trititanium pentoxide to β-phase trititanium pentoxide. In the case of using the time-dependent phase transition trititanium pentoxide as the time-dependent phase transition material, the time-dependent phase transition trititanium pentoxide is used at temperatures lower than 190° C.

The property of at least a portion of crystal grains of λ-phase trititanium pentoxide in the time-dependent phase transition trititanium pentoxide changing into crystal grains of β-phase trititanium pentoxide sometimes alters when pressure is applied to the time-dependent phase transition trititanium pentoxide. In the case of using the time-dependent phase transition trititanium pentoxide as the time-dependent phase transition material, the time-dependent phase transition trititanium pentoxide is normally used in the state where the pressure applied to the time-dependent phase transition trititanium pentoxide is lower than 1 MPa.

In the case of using the time-dependent phase transition trititanium pentoxide as the time-dependent phase transition material, therefore, the time-dependent phase transition trititanium pentoxide is normally used at temperatures of lower than 190° C. and pressures of lower than 1 MPa. The time-dependent phase transition trititanium pentoxide can be sometimes used as a material that undergoes phase transition upon a change in temperature or pressure, in addition to as the time-dependent phase transition material, depending on the phase ratios and grain size of crystal grains of β-phase trititanium pentoxide and λ-phase trititanium pentoxide. When the time-dependent phase transition trititanium pentoxide is used as a material to detect changes in temperature and pressure, instead of the time-dependent phase transition material, the aforementioned use conditions, such as temperatures of lower than 190° C. or pressures of lower than 1 MPa, are not applied.

Hereinafter, a description is given of the relationship between the phase of the time-dependent phase transition trititanium pentoxide and elapsed time from production when the time-dependent phase transition material is the time-dependent phase transition trititanium pentoxide. In the following, a description is given of the relationship between the phase of the time-dependent phase transition trititanium pentoxide and elapsed time from production when the temperature of the time-dependent phase transition trititanium pentoxide is lower than 190° C. and the pressure applied thereto is lower than 1 MPa.

The time-dependent phase transition trititanium pentoxide includes crystal grains of at least λ-phase trititanium pentoxide immediately after production as described above.

The time-dependent phase transition trititanium pentoxide has a property that at least a portion of crystal grains of λ-phase trititanium pentoxide undergoes phase transition with time after production and changes into crystal grains of β-phase trititanium pentoxide.

In addition, the time-dependent phase transition trititanium pentoxide has a property that the amount of λ-phase trititanium pentoxide that has changed into β-phase trititanium pentoxide due to phase transition increases with time after production. The phase transition of the time-dependent phase transition trititanium pentoxide from λ-phase trititanium pentoxide to β-phase trititanium pentoxide develops.

As described above, the time-dependent phase transition trititanium pentoxide has a property that the phase ratio of λ-phase trititanium pentoxide decreases with time after production while the phase ratio of β-phase trititanium pentoxide increases. When the time-dependent phase transition trititanium pentoxide includes X mol % of crystal grains of λ-phase trititanium pentoxide and (100-X) mol % of crystal grains of β-phase trititanium pentoxide immediately after production, the time-dependent phase transition trititanium pentoxide has a property that the value of X decreases with time after production. The time-dependent phase transition trititanium pentoxide sometimes includes components other than λ-phase trititanium pentoxide or β-phase trititanium pentoxide. Examples of such components include TiO₂.

For example, the time-dependent phase transition trititanium pentoxide in which the phase ratio of λ-Ti₃O₅ is about 80 mol % 10 days after production while the balance is β-Ti₃O₅ sometimes decreases in phase ratio of λ-Ti₃O₅ to about 55 mol % without any external stimulus 130 days after production.

The characteristic of the time-dependent phase transition trititanium pentoxide that the phase ratio of λ-phase trititanium pentoxide decreases with time after production while the phase ratio of β-phase trititanium pentoxide increases with time varies from one time-dependent phase transition trititanium pentoxide to another. This characteristic is referred to as a “phase ratio characteristic” hereinafter. The phase ratio characteristic is thought to be determined by the phase ratio of λ-phase to β-phase immediately after production, the size of crystal grains, or the like of the time-dependent phase transition trititanium pentoxide. If the phase ratio characteristic of each time-dependent phase transition trititanium pentoxide is measured in advance, the elapsed time from production of the time-dependent phase transition trititanium pentoxide can be measured by measuring the phase ratio of the λ-phase or β-phase trititanium pentoxide in the time-dependent phase transition trititanium pentoxide.

On the other hand, measuring the phase ratio characteristic of the time-dependent phase transition trititanium pentoxide in advance enables prediction of changes in phase ratios of λ-phase trititanium pentoxide and β-phase trititanium pentoxide with time after production. It is therefore possible to predict a temporal change in physical property of the time-dependent phase transition trititanium pentoxide with time after production thereof based on the phase ratio characteristic acquired in advance. The physical property the temporal change of which is to be predicted (hereinafter, sometimes referred to as a target physical property for temporal change prediction) includes one or more physical properties selected from a group consisting of composition, volume, transmittance, reflectance, electric resistance, and magnetism. Examples of temporal changes in those physical properties include changes in composition, volume, color, electric resistance, and magnetic property. The change in color can be substituted with a change in transmittance or reflectance. As described above, according to the physical property temporal change prediction device 1, which includes the physical property temporal change prediction device body 10 including the time-dependent element 40 made of the time-dependent phase transition trititanium pentoxide, it is possible to predict a temporal change in physical property.

In the physical property temporal change prediction device 1, the target physical property of the time-dependent element 40 for temporal change prediction may be electric resistance. Using an increase with time in electric resistance of the time-dependent element 40, which is made of the time-dependent phase transition trititanium pentoxide, implements an electric circuit breaker. The electric circuit breaker utilizes the effect that electricity becomes less likely to conduct through the time-dependent element 40 with time because the electric resistance of the time-dependent element 40, which is made of the time-dependent phase transition trititanium pentoxide, increases with time.

The electric circuit breaker is composed of the physical property temporal change prediction device 1 and is configured to predict a temporal change in electric resistance of the time-dependent element 40. The electric circuit breaker has the same configuration as that of the physical property temporal change prediction device 1 and is named to show that the electric circuit breaker additionally includes a function to shut off electricity in the physical property temporal change prediction device 1. The structure of the electric circuit breaker is the same as that illustrated as the physical property temporal change prediction device 1 in FIG. 1.

In the physical property temporal change prediction device 1, the target physical property of the time-dependent element 40 for temporal change prediction may be volume. Using a temporal change in volume of the time-dependent element 40, which is made of the time-dependent phase transition trititanium pentoxide, also implements the electric circuit breaker. The electric circuit breaker utilizes the matter that the volume of the time-dependent element 40, which is made of the time-dependent phase transition trititanium pentoxide, decreases with time to cause a failure in electrical connection between the time-dependent element 40 and a member that is in electric contact with the time-dependent element 40.

The electric circuit breaker is composed of the physical property temporal change prediction device 1 and is configured to predict a temporal change in volume of the time-dependent element 40. The electric circuit breaker has the same configuration as that of the physical property temporal change prediction device 1 and is named to show that the electric circuit breaker includes a function to shut off electricity, in addition to the physical property temporal change prediction device 1. The structure of the electric circuit breaker is the same as that illustrated as the physical property temporal change prediction device 1 in FIG. 1.

The time-dependent phase transition trititanium pentoxide has a property that once the crystal structure of crystal grains undergoes phase transition from λ-phase trititanium pentoxide to β-phase trititanium pentoxide with time after production, the crystal state after the phase transition is maintained unless the time-dependent phase transition trititanium pentoxide is heated to 190° C. or higher. The elapsed time from production of the time-dependent phase transition trititanium pentoxide can be therefore calculated by applying the λ-phase ratio or β-phase ratio in the time-dependent phase transition trititanium pentoxide, as an object to be measured in elapsed time, to the phase ratio characteristic measured in advance.

The phase transition characteristic is described in detail. When the sum of the phase ratios of λ-phase trititanium pentoxide and β-phase trititanium pentoxide in the time-dependent phase transition trititanium pentoxide is 100 mol %, the phase ratios of λ-phase trititanium pentoxide and β-phase trititanium pentoxide are normally expressed as follows. In a coordinate system showing the phase ratio (mol %) of λ-phase trititanium pentoxide on the vertical axis and elapsed time from production of the time-dependent phase transition trititanium pentoxide on the horizontal axis, the phase ratio of λ-phase trititanium pentoxide in the time-dependent phase transition trititanium pentoxide exhibits a monotonically decreasing curve (λ-phase ratio curve C_{λ}). In the same coordinate system, the phase ratio of β-phase trititanium pentoxide in the time-dependent phase transition trititanium pentoxide exhibits a monotonically increasing curve (β-phase ratio curve C_{β}).

By applying the λ-phase or β-phase ratio in the time-dependent phase transition trititanium pentoxide, as an object to be measured in elapsed time, to the λ-phase ratio curve C or β-phase ratio curve C_{β}, which are measured in advance, the elapsed time from production of the time-dependent phase transition trititanium pentoxide is calculated. The λ-phase ratio curve C or β-phase ratio curve C_{β} included in the phase ratio characteristic are considered to be determined by the phase ratio of λ-phase to β-phase in the time-dependent phase transition trititanium pentoxide immediately after production thereof, the size of crystal grains thereof, or the like.

The λ-phase ratio curve C or β-phase ratio curve C_{β} intersect in some cases depending on the phase ratio of λ-phase to β-phase to the time-dependent phase transition trititanium pentoxide immediately after production thereof, the size of crystal grains thereof, or the like. The λ-phase ratio curve C_{λ} and β-phase ratio curve C_{β} intersect in some cases when the phase ratio (R_{λ0}) at an elapsed time of 0 from production in the λ-phase ratio curve C_{λ} is greater than the phase ratio (R_{β0}) at an elapsed time of 0 from production in the β-phase ratio curve C_{β}, for example. In the time-dependent phase transition trititanium pentoxide of such a characteristic, the λ-phase ratio and β-phase ratio are reversed at an elapsed time of the intersection (P_{INT}) of the λ-phase ratio curve C_{λ} and β-phase ratio curve C_{β}. Specifically, the λ-phase ratio is greater than the β-phase ratio in a region of elapsed time less than the elapsed time at the intersection P_{INT} while the λ-phase ratio is less than the β-phase ratio in a region of elapsed time greater than the elapsed time at the intersection P_{INT}. By using the time-dependent phase transition trititanium pentoxide of such a characteristic, the reverse of the λ-phase ratio and β-phase ratio facilitates precise detection of elapsed time from production.

In the time-dependent phase transition trititanium pentoxide of the first embodiment, the aforementioned intersection P_{INT} can be adjusted to any elapsed time by controlling the phase ratios of λ-phase trititanium pentoxide and β-phase trititanium pentoxide and the sizes of crystal grains thereof. For example, the time-dependent phase transition trititanium pentoxide can be prepared so that the phase ratio of λ-phase trititanium pentoxide is greater than the phase ratio of β-phase trititanium pentoxide when the elapsed time from production exceeds a predetermined elapsed time. By using the time-dependent phase transition trititanium pentoxide, measurement of the phase ratios of β-phase trititanium pentoxide and λ-phase trititanium pentoxide allows for easy and precise detection of elapsed time from production based on the time at the intersection P_{INT}.

β-phase trititanium pentoxide and λ-phase trititanium pentoxide included in the time-dependent phase transition trititanium pentoxide are different in physical properties. For example, β-phase trititanium pentoxide and λ-phase trititanium pentoxide are different in electric conductivity. Specifically, β-phase trititanium pentoxide has an electric conductivity in the same range as that of many semiconductors while the λ-phase trititanium pentoxide has an electric conductivity in the same range as that of many metals. The elapsed time from production of the time-dependent phase transition trititanium pentoxide can be therefore calculated by measuring the electric conductivity of the time-dependent phase transition trititanium pentoxide with a publicly-known electric conductivity measurement apparatus. Changes in electric conductivity of the time-dependent phase transition trititanium pentoxide are known by measuring electric resistance between two or more electrodes across the time-dependent phase transition trititanium pentoxide, for example.

For example, β-phase trititanium pentoxide and λ-phase trititanium pentoxide are different in color. Specifically, β-phase trititanium pentoxide is red or brownish red, and λ-phase trititanium pentoxide is blue. The elapsed time from production of the time-dependent phase transition trititanium pentoxide can be calculated by visually observing the color of the time-dependent phase transition trititanium pentoxide or evaluating the absorption spectrum of the color to calculate the λ-phase or β-phase ratio of the time-dependent phase transition trititanium pentoxide.

β-phase trititanium pentoxide and λ-phase trititanium pentoxide are different in magnetic property. Specifically, β-phase trititanium pentoxide is non-magnetic, and λ-phase trititanium pentoxide is paramagnetic. The elapsed time from production of the time-dependent phase transition trititanium pentoxide can be calculated by measuring the difference in magnetic property of the time-dependent phase transition trititanium pentoxide with a publicly-known magnetization evaluation apparatus.

The time-dependent phase transition trititanium pentoxide preferably includes crystal grains of β-phase trititanium pentoxide and crystal grains of λ-phase trititanium pentoxide at lower than 350° C. due to good development of phase transition with time after production. In addition, the time-dependent phase transition trititanium pentoxide has the property that at least a portion of crystal grains of β-phase trititanium pentoxide and λ-phase trititanium pentoxide change into crystal grains of titanium dioxide (TiO₂) when heated to 350° C. or higher, for example. The time-dependent phase transition trititanium pentoxide having the property that a portion thereof changes into crystal grains of titanium dioxide (TiO₂) when heated to 350° C. or higher is preferred because of good development of phase transition with time after production.

The aforementioned property of the time-dependent phase transition trititanium pentoxide as the time-dependent phase transition material develops when the average grain size (median size) of crystal grains of the time-dependent phase transition trititanium pentoxide is in a particular range. Specifically, the average grain size (median size) of crystal grains of the time-dependent phase transition trititanium pentoxide is normally 1 to 1000 nm, preferably 10 to 700 nm, and more preferably 100 to 500 nm. The average grain size of crystal grains of the time-dependent phase transition trititanium pentoxide indicates the average grain size of crystal grains of λ-phase trititanium pentoxide and crystal grains of β-phase trititanium pentoxide which constitute the time-dependent phase transition trititanium pentoxide. When the average grain size of crystal grains of the time-dependent phase transition trititanium pentoxide is not in the aforementioned range, solid-solid phase transition with time after production could not develop. Bulk of trititanium pentoxide, which is typically composed of only β-phase trititanium pentoxide, does not undergo solid-solid phase transition developing with time after production in the absence of external stimuli.

The minimum unit functioning as the time-dependent phase transition trititanium pentoxide is crystal grains of trititanium pentoxide having an average grain size within the aforementioned range. The minimum unit functioning as the time-dependent phase transition trititanium pentoxide therefore can be nanoparticles of single-crystal grains having an average particle size within the aforementioned range. However, nanoparticles having an average particle size within the aforementioned range are difficult to handle, and the time-dependent phase transition trititanium pentoxide is normally polycrystal of crystal grains of trititanium pentoxide having an average particle size within the aforementioned range. The form of this polycrystal of crystal grains is not particularly limited and is granular, for example.

In terms of the size of the granular polycrystal of crystal grains, the average particle size (median size) is typically 50 nm to 500 μm, preferably 1 to 50 μm, and more preferably 3 to 8 μm, for example. When the average particle size (median size) of the granular polycrystal of crystal grains is in the aforementioned range, the particles are easy to handle.

The granular polycrystal of crystal grains can be used directly. The granular polycrystal of crystal grains also can be used by being formed into a compact of polycrystal of crystal grains, such as a pellet obtained by compressing a large number of grains of polycrystal of crystal grains, or can be used by being contained in the base material 30. The compact may be shaped without using a mold or may be a molded body produced by using a mold. The time-dependent element 40A of the physical property temporal change prediction device body 10A of the physical property temporal change prediction device 1A according to the first embodiment is a compact made of the time-dependent phase transition material. Specifically, the time-dependent element 40A is a pellet obtained by compressing polycrystal of crystal grains of the time-dependent phase transition trititanium pentoxide as the time-dependent phase transition material.

As described above, the time-dependent element 40 and the time-dependent phase transition trititanium pentoxide as the material thereof undergo phase transition of the crystalline structure of crystal grains from the λ-phase trititanium pentoxide to β-phase trititanium pentoxide with time after production to change in physical property. The time-dependent phase transition trititanium pentoxide also changes in physical property with changes in temperature and pressure in addition to elapsed time, due to phase transition of the crystalline structure of crystal grains between the λ-phase trititanium pentoxide and β-phase trititanium pentoxide or changes in composition of crystal grains into a composition other than trititanium pentoxide. The time-dependent phase transition trititanium pentoxide includes the property of once undergoing phase transition of the crystalline structure of crystal grains or changing in composition of crystal grains with a change in temperature or pressure, maintaining the crystal state after the phase transition or the change in composition.

Hereinafter, a description is given of changes in physical properties of the time-dependent phase transition trititanium pentoxide with changes in temperature. The time-dependent phase transition trititanium pentoxide changes in physical property due to influences of changes in pressure and temperature as described above. The following description is given of changes in physical property of the time-dependent phase transition trititanium pentoxide with a change in temperature under normal pressure.

The time-dependent phase transition trititanium pentoxide normally includes crystal grains of β-phase trititanium pentoxide and crystal grains of λ-phase trititanium pentoxide at lower than 350° C. under normal pressure. The time-dependent phase transition trititanium pentoxide can be produced so as to include only crystal grains of λ-phase trititanium pentoxide immediately after production but normally includes crystal grains of β-phase trititanium pentoxide and crystal grains of λ-phase trititanium pentoxide thereafter.

The time-dependent phase transition trititanium pentoxide includes the property that at least a portion of crystal grains of β-phase trititanium pentoxide undergo phase transition into crystal grains of λ-phase trititanium pentoxide when heated to 190° C. or higher. When the time-dependent phase transition trititanium pentoxide with a phase ratio of λ-phase trititanium pentoxide once reduced with time after production is heated to 190° C. or higher, the phase ratio of λ-phase trititanium pentoxide can be increased again. In such a manner, the time-dependent phase transition trititanium pentoxide is reusable as the time-dependent phase transition material when heated to 190° C. or higher.

In addition, the time-dependent phase transition trititanium pentoxide has the property that at least a portion of crystal grains of β-phase trititanium pentoxide and λ-phase trititanium pentoxide change into crystal grains of titanium dioxide when heated to 350° C. or higher under normal pressure, for example. Specifically, when the time-dependent phase transition trititanium pentoxide is heated to 350° C. or higher, 5 mol % or more of crystal grains of λ-phase trititanium pentoxide change in composition into crystal grains of titanium dioxide. The time-dependent phase transition trititanium pentoxide therefore includes crystal grains of β-phase trititanium pentoxide, crystal grains of λ-phase trititanium pentoxide, and crystal grains of titanium dioxide at 350° C. or higher under normal pressure. Herein, titanium dioxide is an idea including rutile, anatase, and brookite.

Titanium dioxide is different in physical properties from β-phase trititanium pentoxide and λ-phase trititanium pentoxide which constitute the time-dependent phase transition trititanium pentoxide. For example, titanium dioxide, β-phase trititanium pentoxide, and λ-phase trititanium pentoxide are different in electric conductivity. Specifically, titanium dioxide has an electric conductivity in the same range as that of many insulators. On the other hand, β-phase trititanium pentoxide has an electric conductivity in the same range as that of many semiconductors while the λ-phase trititanium pentoxide has an electric conductivity in the same range as that of many metals. The presence of titanium dioxide in the time-dependent phase transition trititanium pentoxide can be therefore confirmed by measuring the difference in electric conductivity of the time-dependent phase transition trititanium pentoxide which has been heated to 350° C. or higher with a publicly-known electric conductivity measurement apparatus.

Titanium dioxide, β-phase trititanium pentoxide, and λ-phase trititanium pentoxide are different in color. Specifically, titanium dioxide, β-phase trititanium pentoxide, and λ-phase trititanium pentoxide are different in color, which are white, red or brownish red, and blue, respectively. The presence of titanium dioxide in the time-dependent phase transition trititanium pentoxide can be confirmed by visually observing the color of the time-dependent phase transition trititanium pentoxide which has been heated to 350° C. or higher or evaluating the absorption spectrum of the color.

Titanium dioxide, β-phase trititanium pentoxide, and λ-phase trititanium pentoxide are different in magnetic property. The presence of titanium dioxide in the time-dependent phase transition trititanium pentoxide is confirmed by measuring the difference in magnetic property in the time-dependent phase transition trititanium pentoxide which has been heated to 350° C. or higher with a publicly-known magnetization evaluation apparatus.

### <Operation of Time-Dependent Element, Physical Property Temporal Change Prediction Device, and Electric Circuit Breaker>

The physical property temporal change prediction device 1A has a function to predict a temporal change in physical property with time after production of the time-dependent element 40 without supply of power or energy by using the characteristic of the time-dependent phase transition trititanium pentoxide as the material of the time-dependent element 40.

The physical property temporal change prediction device 1A is used in a state where the temperature of the physical property temporal change prediction device body 10A is lower than 190° C. and the pressure applied to the physical property temporal change prediction device body 10A is lower than 1 MPa. When the physical property temporal change prediction device body 10A is used under the conditions in which the temperature is not lower than 190° C. and the pressure applied thereto is not lower than 1 MPa, the time-dependent phase transition trititanium pentoxide as the material of the time-dependent element 40 undergoes phase transition induced by heat or pressure. Using the physical property temporal change prediction device body 10A under the conditions in which the temperature is not lower than 190° C. or the pressure applied thereto is not lower than 1 MPa could prevent physical properties from changing with time after production in the time-dependent phase transition trititanium pentoxide as the material of the time-dependent element 40.

In the time-dependent element 40, which constitutes the physical property temporal change prediction device body 10A of the physical property temporal change prediction device 1A, solid-solid phase transition develops with time after production, irrespective of the presence of external stimuli. Specifically, in the time-dependent element 40, at least a portion of crystal grains of λ-phase trititanium pentoxide changes into crystal grains of β-phase trititanium pentoxide.

In the time-dependent element 40, the ratio of phase transition from crystal grains of λ-phase trititanium pentoxide to crystal grains of β-phase trititanium pentoxide increases with time after production. In other words, the time-dependent element 40 has the property that the phase ratio of λ-phase trititanium pentoxide decreases with time after production while the phase ratio of β-phase trititanium pentoxide increases. The characteristic (phase ratio characteristic) of the time-dependent element 40 that the phase ratio of λ-phase trititanium pentoxide decreases with time after production while the phase ratio of β-phase trititanium pentoxide increases varies depending on the time-dependent phase transition trititanium pentoxide that constitutes the time-dependent element 40.

It is therefore possible to measure elapsed time from production of the physical property temporal change prediction device body 10A by measuring the phase ratio characteristic of the time-dependent element 40 constituting the physical property temporal change prediction device body 10A in advance. Specifically, when the phase ratio characteristic of the time-dependent element 40 is measured in advance, measuring the phase ratio of λ-phase or β-phase trititanium pentoxide in the time-dependent element 40 after production allows for measurement of elapsed time from production of the time-dependent element 40. According to the physical property temporal change prediction device 1A, it is possible to measure elapsed time from production of the physical property temporal change prediction device body 10A.

On the other hand, measurement of the phase ratio characteristic of the time-dependent element 40 in advance enables prediction of changes in phase ratios of λ-phase trititanium pentoxide and β-phase trititanium pentoxide with time after production. It is therefore possible to predict temporal changes in physical property of the time-dependent element 40 with time after production thereof based on the phase ratio characteristic acquired in advance. The target physical property for temporal change prediction includes one or more physical properties selected from a group consisting of composition, volume, transmittance, reflectance, electric resistance, and magnetism. Examples of such temporal changes in those physical properties include changes in composition, volume, color, electric resistance, and magnetic property. The change in color can be substituted with a change in transmittance or reflectance. As described above, according to the physical property temporal change prediction device 1 that includes the physical property temporal change prediction device body 10 including the time-dependent element 40, temporal changes in physical property can be predicted.

In the physical property temporal change prediction device 1, the target physical property of the time-dependent element 40 for temporal change prediction may be electric resistance. According to an electric circuit breaker using the electric resistance of the time-dependent element 40 increasing with time, it is possible to shut off electricity based on elapsed time from production. For example, controlling the phase ratio characteristic of the time-dependent phase transition material constituting the time-dependent element 40 implements an electric circuit breaker which allows electricity to flow therethrough during a certain period and prevents electricity from flowing after the period. According to such an electric circuit breaker, it is possible to forcibly stop using batteries or electric equipment that have expired.

In the physical property temporal change prediction device 1, the target physical property of the time-dependent element 40 for temporal change prediction may be volume. An electric circuit breaker using the volume of the time-dependent element 40 changing with time, is able to shut off electricity based on elapsed time from production. For example, controlling the phase ratio characteristic of the time-dependent phase transition material constituting the time-dependent element 40 implements an electric circuit breaker which makes a physical contact to flow electricity during a certain period and then disconnects to stop electric conduction after the period. According to such an electric circuit breaker, it is possible to forcibly stop using batteries and electric equipment that have expired.

The function of the time-dependent element 40 that undergoes solid-solid phase transition developing with time after production irrespective of the presence of external stimuli is based on the characteristic of the time-dependent phase transition trititanium pentoxide itself. It is therefore unnecessary to provide a facility such as a power supply to supply energy to the physical property temporal change prediction device 1A. In addition, when the time-dependent element 40 made of the time-dependent phase transition trititanium pentoxide is heated to a temperature of not lower than 190° C. and lower than 350° C., the phase ratio of λ-phase trititanium pentoxide can be increased again. When the physical property temporal change prediction device body 10A is heat-treated at a temperature of not lower than 190° C. and lower than 350° C., the physical property temporal change prediction device 1A is reusable as the substance to detect a temporal change.

### <Effect of Time-Dependent Element, Physical Property Temporal Change Prediction Device, and Electric Circuit Breaker>

The time-dependent element 40 undergoes phase transition developing with time after production without supply of power or energy. The physical property temporal change prediction device 1A includes the physical property temporal change prediction device body 10A, which is composed of the time-dependent element 40. The physical property temporal change prediction device 1A predicts a temporal change in physical property with time after production of the time-dependent element 40 without supply of power or energy. When the physical property temporal change prediction device 1 is used as an electric circuit breaker, it is possible to shut off electricity based on elapsed time from production.

The characteristic of the time-dependent phase transition trititanium pentoxide as the material of the time-dependent element 40 constituting the physical property temporal change prediction device body 10A that physical properties change with time after production is not influenced by the ambient atmosphere. The physical property temporal change prediction device 1A can be used in an atmosphere of air, oxygen, nitrogen, or the like.

Hereinabove, the operation and effect of the physical property temporal change prediction device 1A in which the time-dependent phase transition material is the time-dependent phase transition trititanium pentoxide are described. The operation and effect thereof are thought to be the same as those in the case where the time-dependent phase transition material is other than the time-dependent phase transition trititanium pentoxide.

### Second Embodiment

FIG. 2 is a schematic perspective view illustrating a physical property temporal change prediction device according to a second embodiment. A physical property temporal change prediction device 1B (1) illustrated in FIG. 2 includes a physical property temporal change prediction device body 10B (10). The physical property temporal change prediction device body 10B is composed of a time-dependent element 40B (40), which is a thin film made of the time-dependent phase transition trititanium pentoxide. The thin-film time-dependent element 40B is formed on a substrate 50. In other words, the physical property temporal change prediction device 1B includes the substrate 50 and the thin-film time-dependent element 40B formed on the substrate 50.

The physical property temporal change prediction device 1B according to the second embodiment (illustrated in FIG. 2) is the same as the physical property temporal change prediction device 1A according to the first embodiment (illustrated in FIG. 1) excepting the shape of the physical property temporal change prediction device body 10B and the provision of the substrate 50. The same members of the physical property temporal change prediction device 1B according to the second embodiment (illustrated in FIG. 2) as the members of the physical property temporal change prediction device 1A according to the first embodiment (illustrated in FIG. 1) are given the same reference symbols, and the description of the configurations and operations thereof is omitted or simplified. The physical property temporal change prediction device 1B can be used as an electric circuit breaker similarly to the physical property temporal change prediction device 1A according to the first embodiment (illustrated in FIG. 1).

### <Physical Property Temporal Change Prediction Device Body>

The physical property temporal change prediction device body 10B is composed of the time-dependent element 40B (40) and does not include substantially any material other than the time-dependent element 40B, similarly to the physical property temporal change prediction device body 10A of the physical property temporal change prediction device 1A according to the first embodiment (illustrated in FIG. 1). The time-dependent element 40B is made of the physical property temporal change trititanium pentoxide which is the same material as that of the time-dependent element 40A of the physical property temporal change prediction device 1A according to the first embodiment (illustrated in FIG. 1). The time-dependent element 40B is formed on the substrate 50.

The time-dependent element 40B is a thin film of the time-dependent phase transition trititanium pentoxide unlike the time-dependent element 40A (illustrated in FIG. 1). According to the thin-film time-dependent element 40B, the thin film improves visibility and facilitates visual evaluation while facilitating evaluation of the absorption spectrum. The thin-film time-dependent element 40B is formed on the substrate 50 by using spin coating, dip coating, sputtering, CVD, laser ablation, aerosol deposition, or the like, for example.

The material of the substrate 50 is not limited particularly. Examples of the material of the substrate 50 are glass, semiconductors such as Si, SiC, and GaN, inorganic oxides such as sapphire, metals such as Al, Cu, Ti, Ni, Sn, Au, Ag, and SUS, and resins such as polyimide resin.

### <Operation of Time-Dependent Element, Physical Property Temporal Change Prediction Device, and Electric Circuit Breaker>

The operations of the time-dependent element 40B are the same as those of the time-dependent element 40A according to the first embodiment (illustrated in FIG. 1), and the description thereof is omitted.

The operations of the physical property temporal change prediction device 1B are the same as those of the physical property temporal change prediction device 1A according to the first embodiment (illustrated in FIG. 1), and the description thereof is omitted.

The operations of the electric circuit breaker composed of the physical property temporal change prediction device 1B are the same as those of the electric circuit breaker composed of the physical property temporal change prediction device 1A according to the first embodiment (illustrated in FIG. 1), and the description thereof is omitted.

The physical property temporal change prediction device 1B includes the substrate 50. The physical property temporal change prediction device 1B therefore has high mechanical strength. The thermal conduction, electric conduction, and the like of the physical property temporal change prediction device 1B can be adjusted by controlling the thermal conduction, electric conduction, and the like of the substrate 50.

### <Effect of Time-Dependent Element, Physical Property Temporal Change Prediction Device, and Electric Circuit Breaker>

The time-dependent element 40B exerts the same effects as those of the time-dependent element 40A according to the first embodiment (illustrated in FIG. 1).

The physical property temporal change prediction device 1B exerts the same effects as those of the physical property temporal change prediction device according to the first embodiment (illustrated in FIG. 1).

The electric circuit breaker composed of the physical property temporal change prediction device 1B exerts the same effects as those of the electric circuit breaker composed of the physical property temporal change prediction device 1A according to the first embodiment (illustrated in FIG. 1).

According to the physical property temporal change prediction device 1B and the electric circuit breaker composed of the same, the time-dependent element 40B is composed of a thin film, so that the visibility thereof is higher than that of the physical property temporal change prediction device 1A and the electric circuit breaker composed of the same.

In addition, the physical property temporal change prediction device 1B includes the substrate 50. The physical property temporal change prediction device 1B and the electric circuit breaker composed of the same therefore have high mechanical strength. The thermal conduction, electric conduction, and the like of the physical property temporal change prediction device 1B and the electric circuit breaker composed of the same, therefore, can be adjusted by controlling the thermal conduction, electric conduction, and the like of the substrate 50.

### Third Embodiment

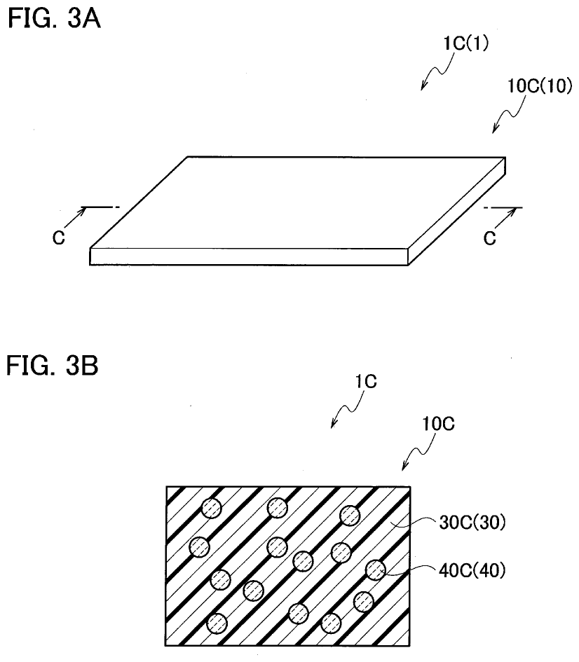

FIG. 3A is a schematic perspective view illustrating a physical property temporal change prediction device according to a third embodiment. FIG. 3B is a schematic cross-sectional view along a line C-C of FIG. 3A. A physical property temporal change prediction device 1C (1) illustrated in FIGS. 3A and 3B includes a physical property temporal change prediction device body 10C (10). The physical property temporal change prediction device body 10C includes a base material 30C (30) and a time-dependent element 40C (40) included in the base material 30C.

The physical property temporal change prediction device 1C according to the third embodiment (illustrated in FIGS. 3A and 3B) is the same as the physical property temporal change prediction device 1A according to the first embodiment (illustrated in FIG. 1) excepting the configuration of the physical property temporal change prediction device body 10C. The same members of the physical property temporal change prediction device 1C according to the third embodiment (illustrated in FIGS. 3A and 3B) as those of the physical property temporal change prediction device 1A according to the first embodiment (illustrated in FIG. 1) are given the same reference symbols, and the description of the configurations and operations thereof is omitted or simplified. The physical property temporal change prediction device 1C can be used as an electric circuit breaker similarly to the physical property temporal change prediction device 1A according to the first embodiment (illustrated in FIG. 1).

### <Physical Property Temporal Change Prediction Device Body>

The physical property temporal change prediction device body 10C includes the base material 30C and the time-dependent element 40C contained in the base material 30C. The base material 30C (illustrated in FIGS. 3A and 3B) has a plate shape, but the shape thereof is not limited particularly.

In the physical property temporal change prediction device body 10C, the time-dependent element 40C is particles 40C made of the time-dependent phase transition trititanium pentoxide. The particles 40C made of the time-dependent phase transition trititanium pentoxide are granular polycrystal of crystal grains of the time-dependent phase transition trititanium pentoxide. The average particle size (median size) of the particles 40C made of the time-dependent phase transition trititanium pentoxide is typically 100 nm to 500 μm, preferably 1 to 50 μm, and more preferably 3 to 8 μm, for example. Granular polycrystal with an average particle size (median size) in the aforementioned ranges is easy to handle.

In the physical property temporal change prediction device body 10C, the base material 30C is used to fix the particles 40C made of the time-dependent phase transition trititanium pentoxide. Specifically, the base material 30C is made of resin. Examples of the resin used for the base material 30C include heat-resistant resin such as polyimide. When the base material 30C is made of heat-resistant resin, the physical property temporal change prediction device 1C can be used at high temperatures because of the high heat resistance thereof. The resin constituting the base material 30C may be hardened resin which is completely hardened or may be gel resin.

As illustrated in FIG. 3B, in the physical property temporal change prediction device body 10C, the particles 40C made of the time-dependent phase transition trititanium pentoxide are dispersed in the base material 30C. The physical property temporal change prediction device body 10C is obtained by adding the particles 40C made of the time-dependent phase transition trititanium pentoxide to the base material 30C which is fluid, followed by mixing and shape forming, for example.

### <Operation of Time-Dependent Element, Physical Property Temporal Change Prediction Device, and Electric Circuit Breaker>

The operation of the time-dependent element 40C are the same as those of the time-dependent element 40A according to the first embodiment (illustrated in FIG. 1), and the description thereof is omitted.

The operations of the physical property temporal change prediction device 1C are the same as those of the physical property temporal change prediction device 1A (illustrated in FIG. 1), excepting that the operation of the time-dependent element 40 is exerted by the granular time-dependent element 40C and the operation based on the base material 30C is exerted. The description of the operations of the physical property temporal change prediction device 1C is omitted.

The operations of the electric circuit breaker composed of the physical property temporal change prediction device 1C are the same as those of the electric circuit breaker according to the first embodiment (illustrated in FIG. 1), excepting the aforementioned two points. The description of the operations of the electric circuit breaker composed of the physical property temporal change prediction device 1C is omitted.

A brief description is given of the matter that the operation of the time-dependent element 40 is exerted in the granular time-dependent element 40C. The granular time-dependent element 40C undergoes solid-solid phase transition developing with time after production irrespective of the presence of external stimuli in a similar manner to the time-dependent element 40A of the physical property temporal change prediction device 1A according to the first embodiment (illustrated in FIG. 1). The time-dependent element 40C is substantially contained in the base material 30C, and changes in physical property of the time-dependent element 40C are indirectly measured through the base material 30C. The operations of the physical property temporal change prediction device 1C are the same as those of the physical property temporal change prediction device 1A according to the first embodiment (illustrated in FIG. 1) excepting the operation in which changes in physical property of the time-dependent element 40C are indirectly measured through the base material 30C.

When the physical property that changes with time after production is color, changes in color of the time-dependent element 40C are observed or measured through the base material 30C. When the physical property that changes with time after production is electric conductivity, changes in electric conductivity of the time-dependent element 40C are measured through the base material 30C.

### (Effect of Time-Dependent Element, Physical Property Temporal Change Prediction Device, and Electric Circuit Breaker)

The time-dependent element 40C exerts the same effects as those of the time-dependent element 40A according to the first embodiment (illustrated in FIG. 1).

The physical property temporal change prediction device 1C exerts the same effects as those of the time-dependent element 40 and physical property temporal change prediction device 1A according to the first embodiment (illustrated in FIG. 1).

The electric circuit breaker composed of the physical property temporal change prediction device 1C exerts the same effects as those of the electric circuit breaker composed of the physical property temporal change prediction device 1A according to the first embodiment (illustrated in FIG. 1).

The physical property temporal change prediction device 1C includes the base material 30C made of resin. The physical property temporal change prediction device 1C and the electric circuit breaker composed of the same therefore have high mechanical strength. According to the physical property temporal change prediction device 1C and the electric circuit breaker composed of the same, the thermal conduction, electric conduction, and the like of the physical property temporal change prediction device 1C and the electric circuit breaker composed of the same can be adjusted by controlling the thermal conduction, electric conduction, and the like of the base material 30C. The thermal conduction, electric conduction, and the like of the base material 30C are adjusted by controlling the material of the resin of the base material 30C, the amount of the base material 30C relative to the time-dependent element 40C, or the like.

Furthermore, the physical property temporal change prediction device 1C and the electric circuit breaker composed of the same include the base material 30C made of resin which is fluid at least during production. The physical property temporal change prediction device 1C and the electric circuit breaker composed of the same are therefore easily formed into any shape.

### Fourth Embodiment

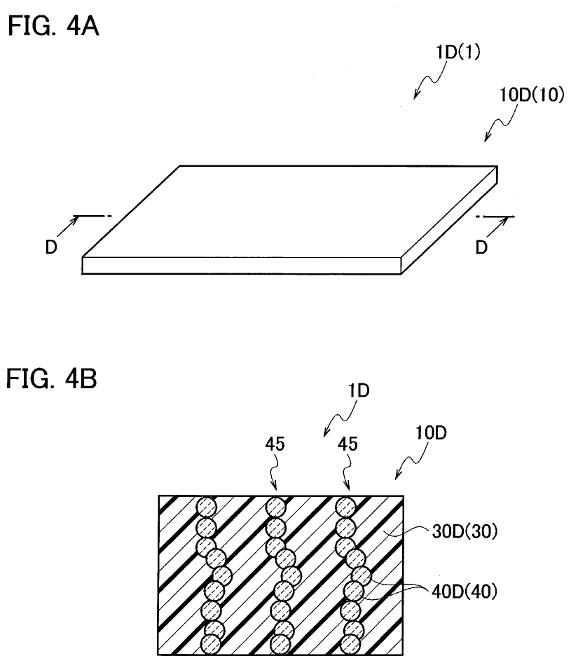

FIG. 4A is a schematic perspective view illustrating a physical property temporal change prediction device according to a fourth embodiment. FIG. 4B is a schematic cross-sectional view along a line D-D of FIG. 4A. A physical property temporal change prediction device 1D (1) illustrated in FIGS. 4A and 4B includes a physical property temporal change prediction device body 10D (10). The physical property temporal change prediction device body 10D includes a base material 30D (30) and a time-dependent element 40D (40) contained in the base material 30D.

The physical property temporal change prediction device 1D according to the fourth embodiment (illustrated in FIGS. 4A and 4B) is the same as the physical property temporal change prediction device 1C according to the third embodiment (illustrated in FIGS. 3A and 3B) excepting the configuration of the physical property temporal change prediction device body 10D. The same members of the physical property temporal change prediction device 1D according to the fourth embodiment (illustrated in FIGS. 4A and 4B) as those of the physical property temporal change prediction device 1C according to the third embodiment (illustrated in FIGS. 3A and 3B) are given the same reference symbols, and the description of the configurations and operations thereof is omitted or simplified. The physical property temporal change prediction device 1D can be used as an electric circuit breaker similarly to the physical property temporal change prediction device 1C according to the third embodiment (illustrated in FIGS. 3A and 3B).

### <Physical Property Temporal Change Prediction Device Body>

The physical property temporal change prediction device body 10D includes the base material 30D and the time-dependent element 40D contained in the base material 30D. The base material 30D (illustrated in FIG. 4A) has a plate shape, but the shape thereof is not limited particularly.

The base material 30D is the same resin as that of the base material 30C used in the physical property temporal change prediction device 1C according to the third embodiment (illustrated in FIGS. 3A and 3B).

In the physical property temporal change prediction device body 10D, the time-dependent element 40D is particles 40D made of the time-dependent phase transition trititanium pentoxide in a similar manner to the time-dependent element 40C used in the physical property temporal change prediction device 1C according to the third embodiment (illustrated in FIGS. 3A and 3B). The particles 40D made of the time-dependent phase transition trititanium pentoxide can be the same as the particles 40C, which are made of the time-dependent phase transition trititanium pentoxide used in the physical property temporal change prediction device 1C according to the third embodiment.

As illustrated in FIG. 4B, in the physical property temporal change prediction device body 10D, the particles 40D made of the time-dependent phase transition trititanium pentoxide are interconnected in groups to form time-dependent phase transition trititanium pentoxide-particle connected bodies 45. In the physical property temporal change prediction device body 10D, the particles 40D made of the time-dependent phase transition trititanium pentoxide are contained in the base material 30D in such a manner that the particles 40D are interconnected in groups. The number of particles 40D interconnected in each time-dependent phase transition trititanium pentoxide-particle connected body 45 may be any value not less than two. In the example of FIG. 4B, the number of particles 40D interconnected in each time-dependent phase transition trititanium pentoxide-particle connected body 45 is nine.

As illustrated in FIG. 4B, the longitudinal direction of the time-dependent phase transition trititanium pentoxide-particle connected bodies 45 is vertical to the front and back surfaces of the physical property temporal change prediction device body 10D. Such an arrangement of the time-dependent phase transition trititanium pentoxide-particle connected bodies 45 is preferred because the arrangement improves the thermal conduction and electric conduction in the vertical direction to the front and back surfaces of the physical property temporal change prediction device body 10D, thereby improving the precision in understanding the situation of the solid-solid phase transition and facilitating heat treatment for reuse. In each time-dependent phase transition trititanium pentoxide-particle connected body 45, two or more particles 40D made of the time-dependent phase transition trititanium pentoxide, which provides higher thermal conduction and higher electric conduction than those of the resin constituting the base material 30D, are interconnected. This provides high thermal conduction and electric conduction between the particles 40D.

The time-dependent phase transition trititanium pentoxide-particle connected bodies 45 may be arranged so that the longitudinal direction of the time-dependent phase transition trititanium pentoxide-particle connected bodies 45 corresponds to the direction perpendicular to the vertical direction to the front and back surfaces of the physical property temporal change prediction device body 10D, that is, the horizontal direction in FIG. 4B (not illustrated). The time-dependent phase transition trititanium pentoxide-particle connected bodies 45 are preferably arranged in such a manner to improve the thermal conduction and electric conduction along the front surface of the physical property temporal change prediction device body 10D and thereby can reduce variation in measurement from one location to another in the front surface of the physical property temporal change prediction device body 10D.

The physical property temporal change prediction device body 10D is obtained by adding the time-dependent phase transition trititanium pentoxide-particle connected bodies 45 into the base material 30D which is fluid, followed by shape forming, for example.

### <Operation of Time-Dependent Element, Physical Property Temporal Change Prediction Device, and Electric Circuit Breaker>

The operations of the time-dependent element 40D are the same as those of the time-dependent element 40C according to the third embodiment illustrated in FIGS. 3A and 3B, and the description thereof is omitted.

The operations of the physical property temporal change prediction device 1D are the same as those of the physical property temporal change prediction device 1C according to the third embodiment, (illustrated in FIGS. 3A and 3B), and the description thereof is omitted.

The operations of the electric circuit breaker composed of the physical property temporal change prediction device 1D are the same as those of the electric circuit breaker composed of the physical property temporal change prediction device 1C according to the third embodiment, (illustrated in FIGS. 3A and 3B), and the description thereof is omitted.

In the physical property temporal change prediction device 1D and the electric circuit breaker composed of the same, the physical property temporal change prediction device body 10D includes the time-dependent phase transition trititanium pentoxide-particle connected bodies 45. The physical property temporal change prediction device 1D and the electric circuit breaker composed of the same therefore allow for more quick observation of a change in physical property in the direction vertical to the front and back surfaces thereof from the front side, compared with the physical property temporal change prediction device 1C and the electric circuit breaker composed of the same.

### <Effect of Time-Dependent Element, Physical Property Temporal Change Prediction Device, and Electric Circuit Breaker>

The time-dependent element 40D exerts the same effects as those of the time-dependent element 40C according to the third embodiment (illustrated in FIGS. 3A and 3B).

The physical property temporal change prediction device 1D exerts the same effects as those of the physical property temporal change prediction device 1C according to the third embodiment (illustrated in FIGS. 3A and 3B).

The electric circuit breaker composed of the physical property temporal change prediction device 1D exerts the same effects as those of the electric circuit breaker composed of the physical property temporal change prediction device 1C according to the third embodiment (illustrated in FIGS. 3A and 3B).

In the physical property temporal change prediction device 1D and the electric circuit breaker composed of the same, the physical property temporal change prediction device body 10D includes the time-dependent phase transition trititanium pentoxide-particle connected bodies 45. The physical property temporal change prediction device 1D and the electric circuit breaker composed of the same allow for quick observation of a change in physical property in the direction vertical to the front and back surfaces thereof from the front side, compared with the physical property temporal change prediction device 1C.

### Fifth Embodiment

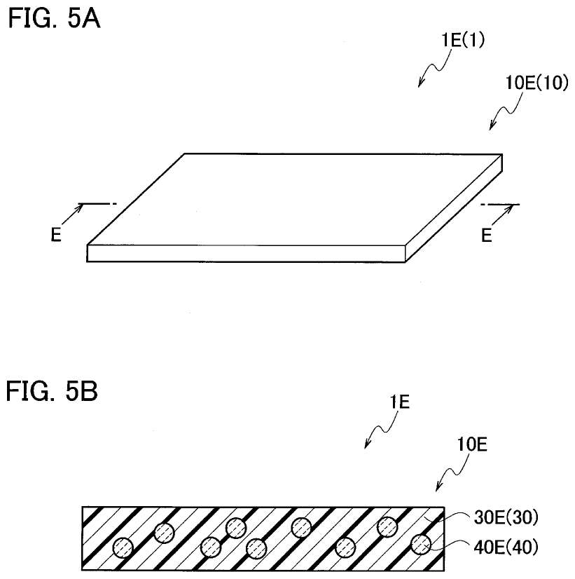

FIG. 5A is a schematic perspective view illustrating a physical property temporal change prediction device according to a fifth embodiment. FIG. 5B is a schematic cross-sectional view along a line E-E of FIG. 5A. A physical property temporal change prediction device 1E (1) illustrated in FIGS. 5A and 5B includes a physical property temporal change prediction device body 10E (10). The physical property temporal change prediction device body 10E includes a base material 30E (30) and a time-dependent element 40E (40) contained in the base material 30E.

The physical property temporal change prediction device 1E according to the fifth embodiment (illustrated in FIGS. 5A and 5B) is the same as the physical property temporal change prediction device 1C according to the third embodiment (illustrated in FIGS. 3A and 3B) excepting the configuration of the physical property temporal change prediction device body 10E. The same members of the physical property temporal change prediction device 1E according to the fifth embodiment (illustrated in FIGS. 5A and 5B) as those of the physical property temporal change prediction device 1C according to the third embodiment (illustrated in FIGS. 3A and 3B) are given the same reference symbols, and the description of the configurations and operations thereof is omitted or simplified. The physical property temporal change prediction device 1E can be used as an electric circuit breaker similar to the physical property temporal change prediction device 1C according to the third embodiment (illustrated in FIGS. 3A and 3B).

### (Physical Property Temporal Change Prediction Device Body)

The physical property temporal change prediction device body 10E includes the base material 30E and the time-dependent element 40E contained in the base material 30E. The base material 30E illustrated in FIGS. 5A and 5B has a plate shape, but the shape thereof is not limited particularly.

The base material 30E is made of film, that is, thin film. Herein, the film refers to a thin film of a dense structure substantially not including any void. The thickness of the base material 30E is 1 mm or less and preferably 1 μm to 1 mm, for example. When the base material 30E is made of a soft material, such as resin, the thickness of the base material 30E is more preferably 1 μm or greater and less than 0.2 mm. When the base material 30E is made of a hard material, such as metal, the thickness of the base material 30E is more preferably 1 μm or greater and less than 0.5 mm. The material of the base material 30E is not limited particularly, and examples thereof are metals, such as Al, Cu, Ti, Ni, Sn, Au, Ag, and SUS and heat-resistance resins such as polyimide. When the base material 30E is made of such a material, the physical property temporal change prediction device 1E can be used at high temperatures because of the high heat resistance thereof.

As illustrated in FIG. 5B, in the physical property temporal change prediction device body 10E, the particles 40E made of the time-dependent phase transition trititanium pentoxide are dispersed in the base material 30E. The physical property temporal change prediction device body 10E is obtained by adding the particles 40E made of the time-dependent phase transition trititanium pentoxide to the base material 30E, which is fluid, followed by mixing and shape forming, for example.

### <Operation of Time-Dependent Element, Physical Property Temporal Change Prediction Device, and Electric Circuit Breaker>

The operations of the time-dependent element 40E are the same as those of the time-dependent element 40C according to the third embodiment illustrated in FIGS. 3A and 3B, and the description thereof is omitted.

The operations of the physical property temporal change prediction device 1E are the same as those of the physical property temporal change prediction device 1C according to the third embodiment (illustrated in FIGS. 3A and 3B), and the description thereof is omitted.

The operations of the electric circuit breaker composed of the physical property temporal change prediction device 1E are the same as those of the electric circuit breaker composed of the physical property temporal change prediction device 1C according to the third embodiment, (illustrated in FIGS. 3A and 3B), and the description thereof is omitted.

The physical property temporal change prediction device 1E and the electric circuit breaker composed of the same are excellent in flexibility since the base material 30E is thin film. The physical property temporal change prediction device 1E and the electric circuit breaker composed of the same are easily attached to or laid on a curved surface.

### <Effect of Time-Dependent Element, Physical Property Temporal Change Prediction Device, and Electric Circuit Breaker>

The time-dependent element 40E exerts the same effects as those of the time-dependent element 40C according to the third embodiment (illustrated in FIGS. 3A and 3B).

The physical property temporal change prediction device 1E exerts the same effects as those of the physical property temporal change prediction device 1C according to the third embodiment (illustrated in FIGS. 3A and 3B).

The electric circuit breaker composed of the physical property temporal change prediction device 1E exerts the same effects as those of the electric circuit breaker composed of the physical property temporal change prediction device 1C according to the third embodiment (illustrated in FIGS. 3A and 3B).

The physical property temporal change prediction device 1E and the electric circuit breaker composed of the same are excellent in flexibility since the base material 30E is thin film. The physical property temporal change prediction device 1E and the electric circuit breaker composed of the same are attached to or laid on a curved surface more easily than the physical property temporal change prediction device 1C and the electric circuit breaker composed of the same.

### Sixth Embodiment

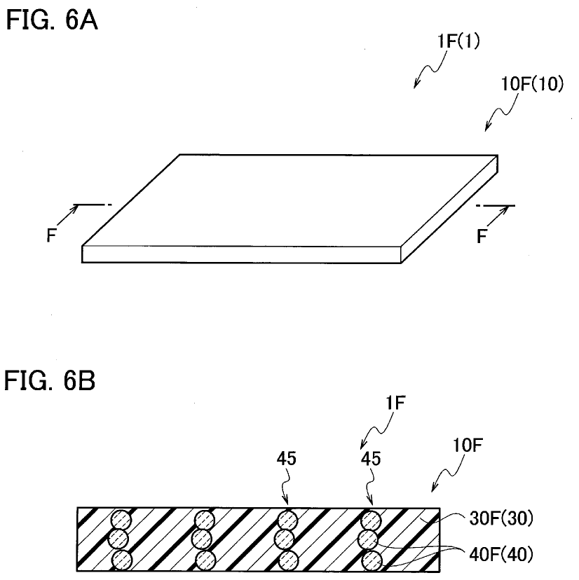

FIG. 6A is a schematic perspective view illustrating a physical property temporal change prediction device according to a sixth embodiment. FIG. 6B is a schematic cross-sectional view along a line F-F of FIG. 6A. A physical property temporal change prediction device 1F (1) illustrated in FIGS. 6A and 6B includes a physical property temporal change prediction device body 10F (10). The physical property temporal change prediction device body 10F includes a base material 30F (30) and a time-dependent element 40F (40) contained in the base material 30F.

The physical property temporal change prediction device 1F according to the sixth embodiment (illustrated in FIGS. 6A and 6B) is the same as the physical property temporal change prediction device 1E according to the fifth embodiment (illustrated in FIGS. 5A and 5B), excepting the configuration of the physical property temporal change prediction device body 10F. The same members of the physical property temporal change prediction device 1F according to the sixth embodiment (illustrated in FIGS. 6A and 6B) as those of the physical property temporal change prediction device 1E according to the fifth embodiment (illustrated in FIGS. 5A and 5B) are given the same reference symbols, and the description of the configurations and operations thereof is omitted or simplified. The physical property temporal change prediction device 1F can be used as an electric circuit breaker similarly to the physical property temporal change prediction device 1E according to the fifth embodiment (illustrated in FIGS. 5A and 5B).

### <Physical Property Temporal Change Prediction Device Body>

The physical property temporal change prediction device body 10F includes the base material 30F and the time-dependent element 40F contained in the base material 30E The base material 30F (illustrated in FIG. 6A) has a plate shape, but the shape thereof is not limited particularly.

The base material 30F is composed of the same film as that of the base material 30E used in the physical property temporal change prediction device 1E according to the fifth embodiment (illustrated in FIGS. 5A and 5B).

In the physical property temporal change prediction device body 10F, the time-dependent element 40F is particles 40E made of the time-dependent phase transition trititanium pentoxide, in a similar manner to the time-dependent element 40E used in the physical property temporal change prediction device 1E according to the fifth embodiment (illustrated in FIGS. 5A and 5B). The particles 40E made of the time-dependent phase transition trititanium pentoxide can be the same as the particles 40E, which are made of the time-dependent phase transition trititanium pentoxide used in the physical property temporal change prediction device 1E according to the fifth embodiment.

As illustrated in FIG. 6B, in the physical property temporal change prediction device body 10F, the particles 40F made of the time-dependent phase transition trititanium pentoxide are interconnected in groups to form the time-dependent phase transition trititanium pentoxide-particle connected bodies 45. In the physical property temporal change prediction device body 10F, the particles 40F made of the time-dependent phase transition trititanium pentoxide are contained in the base material 30F so as to be interconnected in groups. The number of the particles 40F interconnected in each time-dependent phase transition trititanium pentoxide-particle connected body 45 may be any value not less than two. In the example of FIG. 6B, the number of particles 40F interconnected in each time-dependent phase transition trititanium pentoxide-particle connected body 45 is three.

As illustrated in FIG. 6B, the longitudinal direction of the time-dependent phase transition trititanium pentoxide-particle connected bodies 45 is vertical to the front and back surfaces of the physical property temporal change prediction device body 10F. Such an arrangement of the time-dependent phase transition trititanium pentoxide-particle connected bodies 45 is preferred because the arrangement improves the thermal conduction and electric conduction in the vertical direction to the front and back surfaces of the physical property temporal change prediction device body 10F, thereby improving the precision in understanding the situation of solid-solid phase transition or facilitating the heat treatment for reuse. In each time-dependent phase transition trititanium pentoxide-particle connected body 45, two or more particles 40F made of the time-dependent phase transition trititanium pentoxide, which provides higher thermal conduction and higher electric conduction than those of the resin constituting the base material 30F, are interconnected. This provides high thermal conduction and high electric conduction between the particles 40F.

The time-dependent phase transition trititanium pentoxide-particle connected bodies 45 may be arranged so that the longitudinal direction of the time-dependent phase transition trititanium pentoxide-particle connected bodies 45 corresponds to the direction perpendicular to the vertical direction to the front and back surfaces of the temperature sensor body 10F, that is, the horizontal direction in FIG. 6B (not illustrated). Such an arrangement of the time-dependent phase transition trititanium pentoxide-particle connected bodies 45 is preferred because the arrangement improves the thermal conduction and electric conduction along the front surface of the physical property temporal change prediction device body 10F, reducing variation in measurement from one location to another in the front surface of the physical property temporal change prediction device body 10F.

The physical property temporal change prediction device body 10F is obtained by adding the time-dependent phase transition trititanium pentoxide-particle connected bodies 45 into the base material 30F, which is fluid, followed by shape forming, for example.

### <Operation of Time-Dependent Element, Physical Property Temporal Change Prediction Device, and Electric Circuit Breaker>

The operations of the time-dependent element 40F are the same as those of the time-dependent element 40E according to the fifth embodiment (illustrated in FIGS. 5A and 5B), and the description thereof is omitted.

The operations of the physical property temporal change prediction device 1F are the same as those of the physical property temporal change prediction device 1E according to the fifth embodiment, (illustrated in FIGS. 5A and 5B), and the description thereof is omitted.

The operations of the electric circuit breaker composed of the physical property temporal change prediction device 1F are the same as those of the electric circuit breaker composed of the physical property temporal change prediction device 1E according to the fifth embodiment, (illustrated in FIGS. 5A and 5B), and the description thereof is omitted.

In the physical property temporal change prediction device 1F and the electric circuit breaker composed of the same, the physical property temporal change prediction device body 10F includes the time-dependent phase transition trititanium pentoxide-particle connected bodies 45. The physical property temporal change prediction device 1F and the electric circuit breaker composed of the same therefore allow for more quick observation of a change in physical property in the direction vertical to the front and back surfaces thereof, from the front side, compared with the physical property temporal change prediction device 1E and the electric circuit breaker composed of the same.

### <Effect of Time-Dependent Element, Physical Property Temporal Change Prediction Device, and Electric Circuit Breaker>

The time-dependent element 40F exerts the same effects as those of the time-dependent element 40E according to the fifth embodiment (illustrated in FIGS. 5A and 5B).

The physical property temporal change prediction device 1F exerts the same effects as those of the physical property temporal change prediction device 1E according to the fifth embodiment (illustrated in FIGS. 5A and 5B).

The electric circuit breaker composed of the physical property temporal change prediction device 1F exerts the same effects as those of the electric circuit breaker composed of the physical property temporal change prediction device 1E according to the fifth embodiment (illustrated in FIGS. 5A and 5B).

In the physical property temporal change prediction device 1F and the electric circuit breaker composed of the same, the physical property temporal change prediction device body 10F includes the time-dependent phase transition trititanium pentoxide-particle connected bodies 45. The physical property temporal change prediction device 1F and the electric circuit breaker composed of the same allow for more quick observation of a change in physical property in the vertical direction to the front and back surfaces from the front side, compared with the physical property temporal change prediction device 1E and the electric circuit breaker composed of the same, respectively.

### Seventh Embodiment

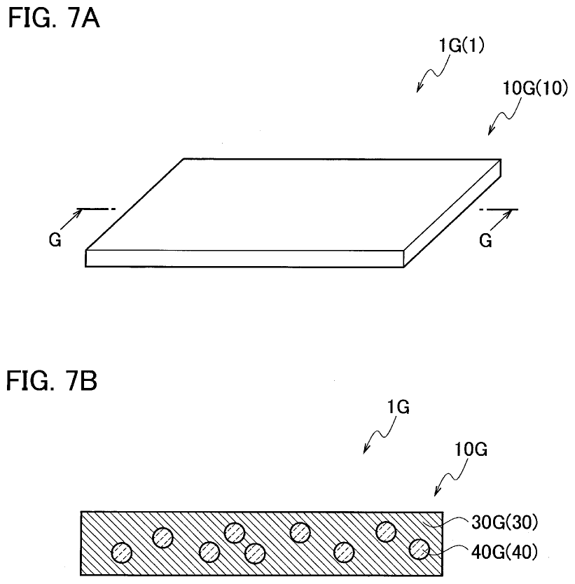

FIG. 7A is a schematic perspective view illustrating a physical property temporal change prediction device according to a seventh embodiment. FIG. 7B is a schematic cross-sectional view along a line G-G of FIG. 7A. A physical property temporal change prediction device 1G (1) illustrated in FIGS. 7A and 7B includes a physical property temporal change prediction device body 10G (10). The physical property temporal change prediction device body 10G includes a base material 30G (30) and a time-dependent element 40G (40) contained in the base material 30G.

The physical property temporal change prediction device 1G according to the seventh embodiment (illustrated in FIGS. 7A and 7B) is the same as the physical property temporal change prediction device 1C according to the third embodiment (illustrated in FIGS. 3A and 3B) excepting the configuration of the physical property temporal change prediction device body 10E. The same members of the physical property temporal change prediction device 1G according to the seventh embodiment (illustrated in FIGS. 7A and 7B,) as those of the physical property temporal change prediction device 1C according to the third embodiment (illustrated in FIGS. 3A and 3B) are given the same reference symbols, and the description of the configurations and operations thereof is omitted or simplified. The physical property temporal change prediction device 1G can be used as an electric circuit breaker similarly to the physical property temporal change prediction device 1C according to the third embodiment (illustrated in FIGS. 3A and 3B).

### (Physical Property Temporal Change Prediction Device Body)

The physical property temporal change prediction device body 10G includes the base material 30G and the time-dependent element 40G contained in the base material 30G.

The base material 30G is a sheet made of woven or non-woven fabric. In this specification, sheets refer to woven or non-woven fabric. The material of the base material 30G is not limited particularly, and examples thereof include glass fibers and carbon fibers. The base material 30G is made of glass or carbon fiber woven fabric, glass or carbon fiber non-woven fabric, or the like, for example. When the base material 30G is made of such a material, the physical property temporal change prediction device 1G can be used at high temperatures because of the high heat resistance thereof.

As illustrated in FIG. 7B, in the physical property temporal change prediction device body 10G, the particles 40G made of the time-dependent phase transition trititanium pentoxide are dispersed or distributed in the base material 30G. The particles 40G made of the time-dependent phase transition trititanium pentoxide are dispersed or distributed in the base material 30G by being trapped between fibers constituting the base material 30G or being adhered to the fibers constituting the base material 30G, for example.

The physical property temporal change prediction device body 10G is obtained by the following manner, for example. The base material 30G is immersed in a solution or slurry including the particles 40G made of the time-dependent phase transition trititanium pentoxide and then taken out so that the particles 40G made of the time-dependent phase transition trititanium pentoxide are dispersed and fixed in voids between fibers constituting the base material 30G.

### <Operation of Time-Dependent Element, Physical Property Temporal Change Prediction Device, and Electric Circuit Breaker>

The operations of the time-dependent element 40G are the same as those of the time-dependent element 40C according to the third embodiment (illustrated in FIGS. 3A and 3B), and the description thereof is omitted.

The operations of the physical property temporal change prediction device 1G are the same as those of the physical property temporal change prediction device 1C according to the third embodiment, (illustrated in FIGS. 3A and 3B), and the description thereof is omitted.

The operations of the electric circuit breaker composed of the physical property temporal change prediction device 1G are the same as those of the electric circuit breaker composed of the physical property temporal change prediction device 1C according to the third embodiment, (illustrated in FIGS. 3A and 3B), and the description thereof is omitted.

Since the base material 30G is a sheet made of woven or non-woven fabric, the physical property temporal change prediction device 1G and the electric circuit breaker composed of the same are excellent in flexibility. The physical property temporal change prediction device 1G and the electric circuit breaker composed of the same are therefore easily attached to or laid on a curved surface.

### <Effect of Time-Dependent Element, Physical Property Temporal Change Prediction Device, and Electric Circuit Breaker>

The time-dependent element 40G exerts the same effects as those of the time-dependent element 40C according to the third embodiment (illustrated in FIGS. 3A and 3B).

The physical property temporal change prediction device 1G exerts the same effects as those of the physical property temporal change prediction device 1C according to the third embodiment (illustrated in FIGS. 3A and 3B).

The electric circuit breaker composed of the physical property temporal change prediction device 1G exerts the same effects as those of the electric circuit breaker composed of the physical property temporal change prediction device 1C according to the third embodiment (illustrated in FIGS. 3A and 3B).

Furthermore, since the base material 30G is a sheet made of woven or non-woven fabric, the physical property temporal change prediction device 1G and the electric circuit breaker composed of the same are excellent in flexibility. The physical property temporal change prediction device 1G and the electric circuit breaker composed of the same are therefore attached to or laid on a curved surface more easily than the physical property temporal change prediction device 1C and the electric circuit breaker composed of the same, respectively.

### Eighth Embodiment

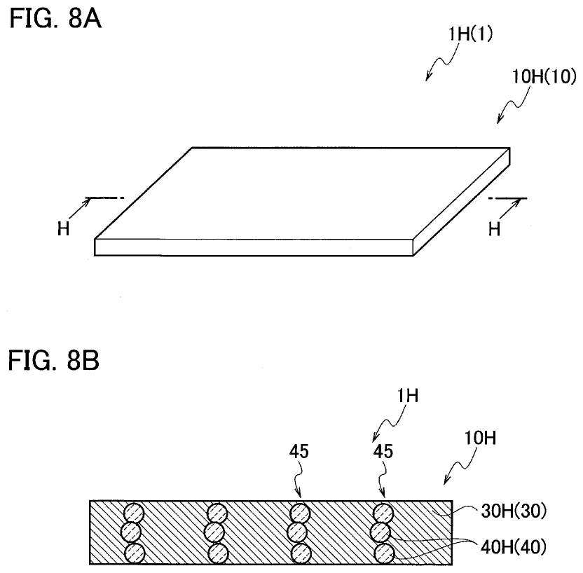

FIG. 8A is a schematic perspective view illustrating a physical property temporal change prediction device according to an eighth embodiment. FIG. 8B is a schematic cross-sectional view along a line H-H of FIG. 8A. A physical property temporal change prediction device 1H (1) illustrated in FIGS. 8A and 8B includes a physical property temporal change prediction device body 10H (10). The physical property temporal change prediction device body 10H includes a base material 30H (30) and a time-dependent element 40H (40) contained in the base material 30H.

The physical property temporal change prediction device 1H according to the eighth embodiment (illustrated in FIGS. 8A and 8B) is the same as the physical property temporal change prediction device 1G according to the seventh embodiment (illustrated in FIGS. 7A and 7B) excepting the configuration of the physical property temporal change prediction device body 10H. The same members of the physical property temporal change prediction device 1H according to the eighth embodiment (illustrated in FIGS. 8A and 8B) as those of the physical property temporal change prediction device 1G according to the seventh embodiment (illustrated in FIGS. 7A and 7B) are given the same reference symbols, and the description of the configurations and operations thereof is omitted or simplified. The physical property temporal change prediction device 1H can be used as an electric circuit breaker similarly to the physical property temporal change prediction device 1G according to the seventh embodiment (illustrated in FIGS. 7A and 7B).

### <Physical Property Temporal Change Prediction Device Body>

The physical property temporal change prediction device body 10H includes the base material 30H and the time-dependent element 40H contained in the base material 30H.

The base material 30H is composed of the same sheet made of woven or non-woven fabric as that of the base material 30G used in the physical property temporal change prediction device 1G according to the seventh embodiment (illustrated in FIGS. 7A and 7B).

In the physical property temporal change prediction device body 10H, the time-dependent element 40H is particles 40H made of the time-dependent phase transition trititanium pentoxide, in a similar manner to the time-dependent element 40G used in the physical property temporal change prediction device 1G according to the seventh embodiment (illustrated in FIGS. 7A and 7B). The particles 40H made of the time-dependent phase transition trititanium pentoxide can be the same as the particles 40G made of the time-dependent phase transition trititanium pentoxide used in the physical property temporal change prediction device 1G according to the seventh embodiment.

As illustrated in FIG. 8B, in the physical property temporal change prediction device body 10H, the particles 40H made of the time-dependent phase transition trititanium pentoxide are interconnected in groups to form the time-dependent phase transition trititanium pentoxide-particle connected bodies 45. In the physical property temporal change prediction device body 10H, the particles 40H made of the time-dependent phase transition trititanium pentoxide are contained in the base material 30H so as to be interconnected in groups. The time-dependent phase transition trititanium pentoxide-particle connected bodies 45 formed by interconnection of the particles 40H made of the time-dependent phase transition trititanium pentoxide are dispersed or distributed in the base material 30H. The time-dependent phase transition trititanium pentoxide-particle connected bodies 45 are dispersed or distributed in the base material 30H by being trapped between fibers constituting the base material 30H or being adhered to the fibers constituting the material 30H, for example.

The number of the particles 40H interconnected in each time-dependent phase transition trititanium pentoxide-particle connected body 45 may be any value not less than two. In the example of FIG. 8B, the number of particles 40H interconnected in each time-dependent phase transition trititanium pentoxide-particle connected body 45 is three.

As illustrated in FIG. 8B, the longitudinal direction of the time-dependent phase transition trititanium pentoxide-particle connected bodies 45 is vertical to the front and back surfaces of the physical property temporal change prediction device body 10H. Such an arrangement of the time-dependent phase transition trititanium pentoxide-particle connected bodies 45 is preferred because the arrangement improves the thermal conduction and electric conduction in the vertical direction to the front and back surfaces of the physical property temporal change prediction device body 10H, thereby improving the precision in understanding the situation of solid-solid phase transition and facilitating the heat treatment for reuse. In each time-dependent phase transition trititanium pentoxide-particle connected body 45, two or more particles 40H made of the time-dependent phase transition trititanium pentoxide that provides higher thermal conduction and higher electric conduction than those of the resin constituting the base material 30H are interconnected. This provides high thermal conduction and high electric conduction between the particles 40H.

The time-dependent phase transition trititanium pentoxide-particle connected bodies 45 may be arranged so that the longitudinal direction of the time-dependent phase transition trititanium pentoxide-particle connected bodies 45 corresponds to the perpendicular direction to the direction vertical to the front and back surfaces of the temperature sensor body 10H, that is, the horizontal direction in FIG. 8B (not illustrated). Such an arrangement of the time-dependent phase transition trititanium pentoxide-particle connected bodies 45 is preferred because the arrangement improves the thermal conduction and electric conduction along the front surface of the physical property temporal change prediction device body 10H and reduces variation in measurement from one location to another in the front surface of the physical property temporal change prediction device body 10H.

The physical property temporal change prediction device body 10H is obtained in the following manner, for example. The base material 30H is immersed in a solution or slurry including the time-dependent phase transition trititanium pentoxide-particle connected bodies 45 and then taken out so that the time-dependent phase transition trititanium pentoxide-particle connected bodies 45 are fixed in voids between fibers constituting the base material 30H.

### <Operation of Time-Dependent Element, Physical Property Temporal Change Prediction Device, and Electric Circuit Breaker>

The operations of the time-dependent element 40H are the same as those of the time-dependent element 40G according to the seventh embodiment (illustrated in FIGS. 7A and 7B), and the description thereof is omitted.

The operations of the physical property temporal change prediction device 1H are the same as those of the physical property temporal change prediction device 1G according to the seventh embodiment (illustrated in FIGS. 7A and 7B), and the description thereof is omitted.

The operations of the electric circuit breaker composed of the physical property temporal change prediction device 1H are the same as those of the electric circuit breaker composed of the physical property temporal change prediction device 1G according to the seventh embodiment, (illustrated in FIGS. 7A and 7B), and the description thereof is omitted.

In the physical property temporal change prediction device 1H and the electric circuit breaker composed of the same, the physical property temporal change prediction device body 10H includes the time-dependent phase transition trititanium pentoxide-particle connected bodies 45. The physical property temporal change prediction device 1H and the electric circuit breaker composed of the same therefore allow for more quick observation of a change in physical property in the vertical direction to the front and back surfaces, from the front side, compared with the physical property temporal change prediction device 1G and the electric circuit breaker, respectively.

### <Effect of Time-Dependent Element, Physical Property Temporal Change Prediction Device, and Electric Circuit Breaker>

The time-dependent element 40H exerts the same effects as those of the time-dependent element 40G according to the seventh embodiment (illustrated in FIGS. 7A and 7B).

The physical property temporal change prediction device 1H exerts the same effects as those of the physical property temporal change prediction device 1G according to the seventh embodiment (illustrated in FIGS. 7A and 7B).

The electric circuit breaker composed of the physical property temporal change prediction device 1H exerts the same effects as those of the electric circuit breaker composed of the physical property temporal change prediction device 1G according to the seventh embodiment (illustrated in FIGS. 7A and 7B).

In the physical property temporal change prediction device 1H and the electric circuit breaker composed of the same, the physical property temporal change prediction device body 10H includes the time-dependent phase transition trititanium pentoxide-particle connected bodies 45. The physical property temporal change prediction device 1H and the electric circuit breaker composed of the same therefore allow for quick observation of a change in physical property in the vertical direction to the front and back surfaces from the front side, compared with the physical property temporal change prediction device 1G and the electric circuit breaker composed of the same, respectively.

### Ninth Embodiment

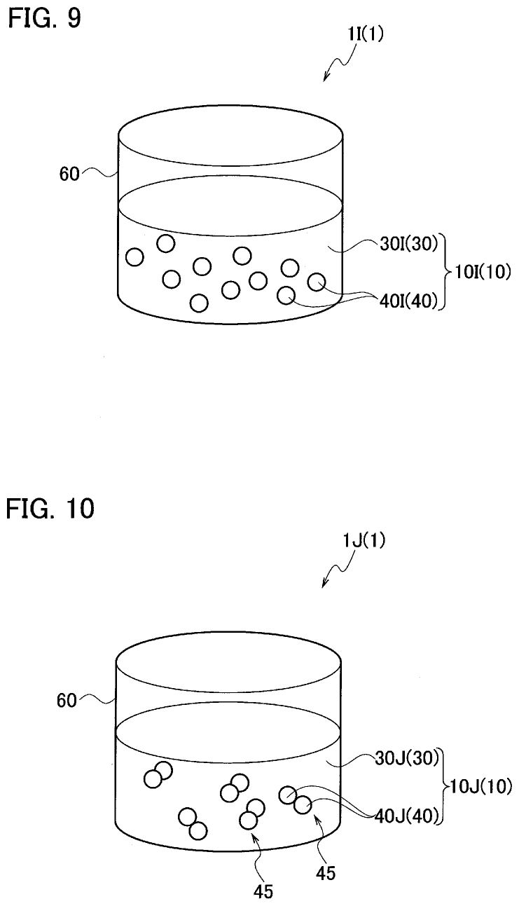

FIG. 9 is a schematic perspective view illustrating a physical property temporal change prediction device according to a ninth embodiment. A physical property temporal change prediction device 1I (1) illustrated in FIG. 9 includes a physical property temporal change prediction device body 10I (10). The physical property temporal change prediction device body 10I includes a base material 30I (30) and a time-dependent element 40I (40) contained in the base material 30I. The physical property temporal change prediction device body 10I is in the form of slurry or gel. The physical property temporal change prediction device body 10I, which is fluid, is accommodated in a container 60. The physical property temporal change prediction device 1I includes the physical property temporal change prediction device body 10I and the container 60 accommodating the physical property temporal change prediction device body 10I.

The physical property temporal change prediction device 1I according to the ninth embodiment (illustrated in FIG. 9) is the same as the physical property temporal change prediction device 1C according to the third embodiment (illustrated in FIGS. 3A and 3B) excepting the configuration of the physical property temporal change prediction device body 10I. The same members of the physical property temporal change prediction device 1I according to the ninth embodiment (illustrated in FIG. 9) as those of the physical property temporal change prediction device 1C according to the third embodiment (illustrated in FIGS. 3A and 3B) are given the same reference symbols, and the description of the configurations and operations thereof is omitted or simplified. The physical property temporal change prediction device 1I can be used as an electric circuit breaker similarly to the physical property temporal change prediction device 1C according to the third embodiment (illustrated in FIGS. 3A and 3B).

### <Physical Property Temporal Change Prediction Device Body>

The physical property temporal change prediction device body 10I includes the base material 30I and the time-dependent element 40I contained in the base material 30I.

The base material 30I is liquid or gel. The material of the base material 30I is not limited particularly and is a publicly-known organic or inorganic solvent or the like, for example. Examples of the inorganic solvent include water. The base material 30I is suitably made of an organic or inorganic solvent because when slurry including the base material 30I and time-dependent element 40I is sprayed onto an object, the base material 30I easily volatilizes with only the time-dependent element 40I easily fixed to the object. When the base material 30I is made of gel and the gel including the base material 30I and time-dependent element 40I is sprayed onto an object, the time-dependent element 40I in the gel easily adheres to or is fixed to the object.

As illustrated in FIG. 9, in the physical property temporal change prediction device body 10I, the particles 40I made of the time-dependent phase transition trititanium pentoxide are dispersed in the base material 30I. The physical property temporal change prediction device body 10I is obtained by adding the particles 40I made of the time-dependent phase transition trititanium pentoxide to the base material 30I, followed by mixing, for example.

### <Operation of Time-Dependent Element, Physical Property Temporal Change Prediction Device, and Electric Circuit Breaker>

The operations of the time-dependent element 40I are the same as those of the time-dependent element 40C according to the third embodiment (illustrated in FIGS. 3A and 3B), and the description thereof is omitted.

The operations of the physical property temporal change prediction device 1I and the electric circuit breaker composed of the same depend on whether the physical property temporal change prediction device body 10I includes the base material 30I in the process of measuring the physical property of an object. Herein, the case where the physical property temporal change prediction device body 10I includes the base material 30I in the process of measuring the physical property of an object includes a case where the physical property temporal change prediction device body 10I is used flowing within the object, such as a pipe, for example. The case where the physical property temporal change prediction device body 10I does not include the base material 30I in the process of measuring the physical property of an object includes a case where the physical property temporal change prediction device body 10I is sprayed onto the object to vaporize the base material 30I with only the time-dependent element 40I fixed for use.

The operations of the physical property temporal change prediction device 1I in the case where the physical property temporal change prediction device body 10I includes the base material 30I in the process of measuring the physical property of an object are substantially the same as those of the physical property temporal change prediction device 1C according to the third embodiment (illustrated in FIGS. 3A and 3B). This is because the base material 30 is interposed between the time-dependent element 40I and the object. The description of the operations in this case is omitted. The physical property temporal change prediction device body 10I is suitably used flowing within the object, such as a pipe. This allows for measurement of the physical property in sections where it is difficult to measure the physical property from the outside of the pipe.

The operations of the physical property temporal change prediction device 1I in the case where the physical property temporal change prediction device body 10I does not include the base material 30I in the process of measuring the physical property of the object are substantially the same as those of the physical property temporal change prediction device 1A according to the first embodiment (illustrated in FIG. 1). This is because the base material 30 is not interposed between the time-dependent element 40I and the object. The description of the operations in this case is omitted. The physical property temporal change prediction device 1I is suitably used in such a manner that the physical property temporal change prediction device body 10I is sprayed onto the object to vaporize the base material 30I with only the time-dependent element 40I fixed. This allows for measurement of the physical property in just the section on which the physical property temporal change prediction device body 10I is sprayed.

### <Effect of Time-Dependent Element, Physical Property Temporal Change Prediction Device, and Electric Circuit Breaker>

The time-dependent element 40I exerts the same effects as those of the time-dependent element 40I according to the third embodiment (illustrated in FIGS. 3A and 3B).

The physical property temporal change prediction device 1I exerts the same effects as those of the physical property temporal change prediction device 1A according to the first embodiment (illustrated in FIG. 1) or the physical property temporal change prediction device 1C according to the third embodiment (illustrated in FIGS. 3A and 3B).

The electric circuit breaker composed of the physical property temporal change prediction device 1I exerts the same effects as those of the electric circuit breaker composed of the physical property temporal change prediction device 1A according to the first embodiment (illustrated in FIG. 1) or the electric circuit breaker composed of the physical property temporal change prediction device 1C according to the third embodiment (illustrated in FIGS. 3A and 3B).

### 10th Embodiment

FIG. 10 is a schematic perspective view illustrating a physical property temporal change prediction device according to a 10th embodiment. A physical property temporal change prediction device 1J (1) illustrated in FIG. 10 includes a physical property temporal change prediction device body 10J (10). The physical property temporal change prediction device body 10J includes a base material 30J (30) and a time-dependent element 40J (40) contained in the base material 30J.

The physical property temporal change prediction device 1J according to the 10th embodiment (illustrated in FIG. 10) is the same as the physical property temporal change prediction device 1I according to the ninth embodiment (illustrated in FIG. 9), excepting the configuration of the physical property temporal change prediction device body 10J. The same members of the physical property temporal change prediction device physical property temporal change prediction device 1J according to the 10th embodiment (illustrated in FIG. 10) as those of the physical property temporal change prediction device 1I according to the ninth embodiment (illustrated in FIG. 9) are given the same reference symbols, and the description of the configurations and operations thereof is omitted or simplified. The physical property temporal change prediction device 1J can be used as an electric circuit breaker similarly to the physical property temporal change prediction device 1I according to the ninth embodiment (illustrated in FIG. 9).

### <Physical Property Temporal Change Prediction Device Body>

The physical property temporal change prediction device body 10J includes the base material 30J and the time-dependent element 40J contained in the base material 30J.

The base material 30J is the same as the base material 30I used in the physical property temporal change prediction device 1I according to the ninth embodiment (illustrated in FIG. 9).

In the physical property temporal change prediction device body 10J, the time-dependent element 40J is particles 40J made of the time-dependent phase transition trititanium pentoxide, in a similar manner to the time-dependent element 40I used in the physical property temporal change prediction device 1I according to the ninth embodiment (illustrated in FIG. 9). The particles 40J made of the time-dependent phase transition trititanium pentoxide may be the same as the particles 40I made of the time-dependent phase transition trititanium pentoxide used in the physical property temporal change prediction device 1I according to the ninth embodiment (illustrated in FIG. 9).

As illustrated in FIG. 10, in the physical property temporal change prediction device body 10J, the particles 40J made of the time-dependent phase transition trititanium pentoxide are interconnected in groups to form the time-dependent phase transition trititanium pentoxide-particle connected bodies 45. In the physical property temporal change prediction device body 10J, the particles 40J made of the time-dependent phase transition trititanium pentoxide are contained in the base material 30J so as to be interconnected in groups. The number of particles 40J interconnected in each time-dependent phase transition trititanium pentoxide-particle connected body 45 may be any value not less than two. In the example of FIG. 10, the number of particles 40J interconnected in each time-dependent phase transition trititanium pentoxide-particle connected body 45 is two.

The physical property temporal change prediction device body 10J is obtained by adding the time-dependent phase transition trititanium pentoxide-particle connected bodies 45 which are composed of the particles 40J made of the time-dependent phase transition trititanium pentoxide and interconnected in groups, to the base material 30J, followed by mixing, for example.

### <Operation of Time-Dependent Element, Physical Property Temporal Change Prediction Device, and Electric Circuit Breaker>

The operations of the time-dependent element 40J are the same as those of the time-dependent element 40I according to the ninth embodiment (illustrated in FIG. 9), and the description thereof is omitted.

The operations of the physical property temporal change prediction device 1J are the same as those of the physical property temporal change prediction device 1I according to the ninth embodiment (illustrated in FIG. 9), and the description thereof is omitted.

The operations of the electric circuit breaker composed of the physical property temporal change prediction device 1J are the same as those of the electric circuit breaker composed of the physical property temporal change prediction device 1I according to the ninth embodiment, (illustrated in FIG. 9), and the description thereof is omitted.

### <Effect of Time-Dependent Element, Temporal Change Prediction Device, and Electric Circuit Breaker>

The time-dependent element 40J exerts the same effects as those of the time-dependent element 40I according to the ninth embodiment (illustrated in FIG. 9).

The physical property temporal change prediction device 1J exerts the same effects as those of the physical property temporal change prediction device 1I according to the ninth embodiment (illustrated in FIG. 9).

The electric circuit breaker composed of the physical property temporal change prediction device 1J exerts the same effects as those of the electric circuit breaker composed of the physical property temporal change prediction device 1I according to the ninth embodiment (illustrated in FIG. 9).

### 11th Embodiment

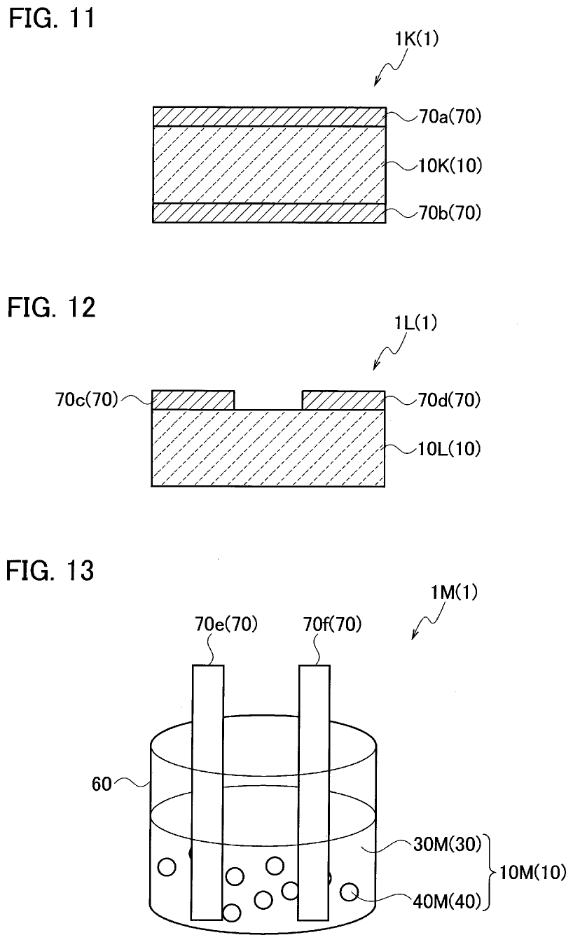

FIG. 11 is a schematic cross-sectional view illustrating a physical property temporal change prediction device according to an 11th embodiment. A physical property temporal change prediction device 1K (1) illustrated in FIG. 11 includes a physical property temporal change prediction device body 10K (10) and electrodes 70a and 70b (70), which are in contact with the physical property temporal change prediction device body 10K.

The physical property temporal change prediction device body 10K (10) (illustrated in FIG. 11) may have any shape. The shape of the physical property temporal change prediction device body 10K (10) may be a columnar shape like the physical property temporal change prediction device body 10A (illustrated in FIG. 1) or a plate shape like the physical property temporal change prediction device body 10C (illustrated in FIG. 3A).

As illustrated in FIG. 11, the electrodes 70a and 70b are provided so as to sandwich the physical property temporal change prediction device body 10K. The electrodes 70a and 70b may have any shape. The electrodes 70 which are in contact with the physical property temporal change prediction device body 10K can include two or more electrodes 70 on each side of the physical property temporal change prediction device body 10K (not illustrated).

The physical property temporal change prediction device body 10K constituting the physical property temporal change prediction device 1K is not limited particularly. Examples of the physical property temporal change prediction device body 10K include the physical property temporal change prediction device bodies 10A to 10H, which constitute the physical property temporal change prediction devices 1A to 1H of the aforementioned first to eighth embodiments.

The material of the electrodes 70 constituting the physical property temporal change prediction device 1K is not limited particularly. Examples thereof are metals such as Al, Ag, and Au, conducting oxides such as ITO, conducting polymers, and carbon materials such as graphite.

The physical property temporal change prediction device 1K can be used as an electric circuit breaker in a similar manner to the physical property temporal change prediction device 1A according to the first embodiment (illustrated in FIG. 1).

### <Operation of Time-Dependent Element, Physical Property Temporal Change Prediction Device, and Electric Circuit Breaker>

The operations of the time-dependent element included in the physical property temporal change prediction device body 10K are the same as those of the time-dependent element 40A according to the first embodiment (illustrated in FIG. 1), and the description thereof is omitted.

As described above, β-phase trititanium pentoxide and λ-phase trititanium pentoxide have different electric conductivities. For example, β-phase trititanium pentoxide has an electric conductivity in the same range as that of many semiconductors while λ-phase trititanium pentoxide has an electric conductivity in the same range as that of many metals. Such a difference in electric conductivity is maintained even after long-term use of the time-dependent phase transition trititanium pentoxide.

The physical property temporal change prediction device 1K is caused to function as a physical property temporal change prediction device by using the electrodes 70a and 70b (70) to measure the electric conductivity of the time-dependent element 40 constituting the physical property temporal change prediction device body 10K.

The operations of the electric circuit breaker composed of the physical property temporal change prediction device 1K integrate the operations of the electric circuit breaker composed of the physical property temporal change prediction device 1A according to the first embodiment and the operation of measuring the electric conductivity using the electrodes 70 (illustrated in FIG. 1), and the description thereof is omitted.

### <Effect of Time-Dependent Element, Physical Property Temporal Change Prediction Device, and Electric Circuit Breaker>

The time-dependent element contained in the physical property temporal change prediction device body 10K exerts the same effects as those of the time-dependent element 40A according to the first embodiment (illustrated in FIG. 1).

According to the physical property temporal change prediction device 1K, the electrodes 70 are used to measure the electric conductivity of the time-dependent element 40 constituting the physical property temporal change prediction device body 10K. The physical property temporal change prediction device 1K thereby exerts the same effects as those of the physical property temporal change prediction device 1A (illustrated in FIG. 1) or the physical property temporal change prediction device 1C (illustrated in FIGS. 3A and 3B).

The electric circuit breaker composed of the physical property temporal change prediction device 1K exerts the same effects as those of the electric circuit breaker composed of the physical property temporal change prediction device 1A according to the first embodiment (illustrated in FIG. 1).

### 12th Embodiment

FIG. 12 is a schematic cross-sectional view illustrating a physical property temporal change prediction device according to a 12th embodiment. A physical property temporal change prediction device 1L (1) illustrated in FIG. 12 includes a physical property temporal change prediction device body 10L (10) and electrodes 70c and 70d (70), which are in contact with the physical property temporal change prediction device body 10L.

The physical property temporal change prediction device body 10L (10) (illustrated in FIG. 12) may have any shape. The shape of the physical property temporal change prediction device body 10L (10) may be a columnar shape like the physical property temporal change prediction device body 10A (illustrated in FIG. 1) or a plate shape like the physical property temporal change prediction device body 10C (illustrated in FIG. 3A).

As illustrated in FIG. 12, the electrodes 70c and 70d are provided so as to sandwich the physical property temporal change prediction device body 10L. The electrodes 70c and 70d may have any shape.

The physical property temporal change prediction device body 10L constituting the physical property temporal change prediction device 1L is the same as the physical property temporal change prediction device body 10K constituting the physical property temporal change prediction device 1K of the aforementioned 11th embodiment, for example.

The physical property temporal change prediction device 1L can be used as an electric circuit breaker in a similar manner to the physical property temporal change prediction device 1A according to the first embodiment (illustrated in FIG. 1).

### <Operation of Time-Dependent Element, Physical Property Temporal Change Prediction Device, and Electric Circuit Breaker>

The operations of the time-dependent element included in the physical property temporal change prediction device body 10L are the same as those of the time-dependent element included in the physical property temporal change prediction device body 10K according to the 11th embodiment (illustrated in FIG. 11), and the description thereof is omitted.

The operations of the physical property temporal change prediction device 1L are the same as those of the physical property temporal change prediction device 1K according to the 11th embodiment, (illustrated in FIG. 11), and the description thereof is omitted.

The operations of the electric circuit breaker composed of the physical property temporal change prediction device 1L are the same as those of the electric circuit breaker composed of the physical property temporal change prediction device 1K according to the 11th embodiment, (illustrated in FIG. 11), and the description thereof is omitted.

### (Effect of Time-Dependent Element, Temporal Change Prediction Device, and Electric Circuit Breaker)

The time-dependent element included in the physical property temporal change prediction device body 10K exerts the same effects as those of the time-dependent element 40A according to the first embodiment (illustrated in FIG. 1).

The physical property temporal change prediction device 1L exerts the same effects as those of the physical property temporal change prediction device 1K according to the 11th embodiment (illustrated in FIG. 11).

The electric circuit breaker composed of the physical property temporal change prediction device 1L exerts the same effects as those of the electric circuit breaker composed of the physical property temporal change prediction device 1K according to the 11th embodiment (illustrated in FIG. 11).

### 13th Embodiment

FIG. 13 is a schematic perspective view illustrating a physical property temporal change prediction device according to a 13th embodiment. A physical property temporal change prediction device 1M (1) (illustrated in FIG. 13) includes a physical property temporal change prediction device body 10M (10) and electrodes 70e and 70f (70) which are in contact with the physical property temporal change prediction device body 10M. As illustrated in FIG. 13, the electrodes 70e and 70f are partially immersed in the physical property temporal change prediction device body 10M. The electrodes 70 which are in contact with the physical property temporal change prediction device body 10M can include two or more electrodes 70, which are not illustrated.

The physical property temporal change prediction device body 10M includes a base material 30M (30) and a time-dependent element 40M (40) contained in the base material 30M. The physical property temporal change prediction device body 10M is in the form of slurry or gel. The physical property temporal change prediction device body 10M, which is fluid, is accommodated in the container 60. The physical property temporal change prediction device 1I includes the physical property temporal change prediction device body 10M and the container 60 accommodating the physical property temporal change prediction device body 10M.

The physical property temporal change prediction device 1M according to the 13th embodiment (illustrated in FIG. 13) includes the electrodes 70e and 70f (70) which are in contact with the physical property temporal change prediction device body 10M, in addition to the physical property temporal change prediction device 1I according to the ninth embodiment (illustrated in FIG. 9). The configuration of the physical property temporal change prediction device 1M is substantially the same as that of the physical property temporal change prediction device 1I according to the ninth embodiment (illustrated in FIG. 9), excepting the configuration of the electrodes 70e and 70f (70). The description of the configurations other than the electrodes 70e and 70f (70) is omitted. The physical property temporal change prediction device 1M can be used as an electric circuit breaker in a similar manner to the physical property temporal change prediction device 1I according to the ninth embodiment (illustrated in FIG. 9).

The material and operations of the electrodes 70e and 70f (70) are the same as those of the electrodes 70a and 70b (70) of the physical property temporal change prediction device 1K according to the 11th embodiment (illustrated in FIG. 11) although the shapes thereof are different. The description of the electrodes 70e and 70f is omitted.

### <Operation of Time-Dependent Element, Physical Property Temporal Change Prediction Device, and Electric Circuit Breaker>

The operations of the time-dependent element 40M are the same as those of the time-dependent element 40C according to the third embodiment (illustrated in FIGS. 3A and 3B), and the description thereof is omitted.

The operations of the physical property temporal change prediction device 1M integrate the operations of the physical property temporal change prediction device 1I according to the ninth embodiment (illustrated in FIG. 9) and the operations of the physical property temporal change prediction device 1K according to the 11th embodiment (illustrated in FIG. 11). The description of the operations is omitted.

The operations of the electric circuit breaker composed of the physical property temporal change prediction device 1M integrate the operations of the electric circuit breaker composed of the physical property temporal change prediction device 1I according to the ninth embodiment (illustrated in FIG. 9) and the operations of the electric circuit breaker composed of the physical property temporal change prediction device 1K according to the 11th embodiment (illustrated in FIG. 11). The description of the operations is omitted.

### <Effect of Time-Dependent Element, Physical Property Temporal Change Prediction Device, and Electric Circuit Breaker>

The time-dependent element 40M exerts the same effects as those of the time-dependent element 40C according to the third embodiment (illustrated in FIGS. 3A and 3B).

The physical property temporal change prediction device 1M exerts the same effects as those of the physical property temporal change prediction device 1I according to the ninth embodiment (illustrated in FIG. 9) and the physical property temporal change prediction device 1K according to the 11th embodiment (illustrated in FIG. 11).

The electric circuit breaker composed of the physical property temporal change prediction device 1M exerts the same effects as those of the electric circuit breaker composed of the physical property temporal change prediction device 1I according to the ninth embodiment (illustrated in FIG. 9) and the electric circuit breaker composed of the physical property temporal change prediction device 1K according to the 11th embodiment (illustrated in FIG. 11).

### Modification of 13th Embodiment

In the physical property temporal change prediction device body 10M according to the 13th embodiment (illustrated in FIG. 13), the particles 40M made of the time-dependent phase transition trititanium pentoxide are dispersed in the base material 30M in a similar manner to the physical property temporal change prediction device body 10I according to the ninth embodiment (illustrated in FIG. 9).

As a modification of the 13th embodiment, the physical property temporal change prediction device body 10J of the physical property temporal change prediction device 1J according to the 10th embodiment (illustrated in FIG. 10) may be used instead of the physical property temporal change prediction device body 10M. As the modification of the 13th embodiment, the particles 40 made of the time-dependent phase transition trititanium pentoxide may be contained in the base material 30 so as to be interconnected in groups in the physical property temporal change prediction device body 10.

The operations of the physical property temporal change prediction device according to the modification integrate the operations of the physical property temporal change prediction device 1J according to the 10th embodiment (illustrated in FIG. 10) and the operations of the physical property temporal change prediction device 1K according to the 11th embodiment (illustrated in FIG. 11). The description of the operations is omitted. The physical property temporal change prediction device according to the modification can be used as an electric circuit breaker similarly to the physical property temporal change prediction device 1I according to the ninth embodiment (illustrated in FIG. 9).

### <Effect of Time-Dependent Element, Temporal Change Prediction Device, and Electric Circuit Breaker>

The time-dependent element included in the modification of the physical property temporal change prediction device 1M exerts the same effects as those of the time-dependent element 40C according to the third embodiment (illustrated in FIGS. 3A and 3B).

The modification of the physical property temporal change prediction device 1M exerts the same effects as those of the physical property temporal change prediction device 1J according to the 10th embodiment (illustrated in FIG. 10) and the physical property temporal change prediction device 1K according to the 11th embodiment (illustrated in FIG. 11).

The electric circuit breaker composed of the modification of the physical property temporal change prediction device 1M exerts the same effects as those of the electric circuit breaker composed of the physical property temporal change prediction device 1I according to the ninth embodiment (illustrated in FIG. 9) and the electric circuit breaker composed of the physical property temporal change prediction device 1K according to the 11th embodiment (illustrated in FIG. 11).

In the aforementioned description of the first to 13th embodiments and the modification, the time-dependent phase transition material is the time-dependent phase transition trititanium pentoxide. However, the time-dependent phase transition material may be a substance other than the time-dependent phase transition trititanium pentoxide in the aforementioned embodiments. The operations and effects of the aforementioned embodiments in the case where the time-dependent phase transition material is a substance other than the time-dependent phase transition trititanium pentoxide are the operations and effects based on the characteristic of the time-dependent phase transition material changing in physical property with time after production.

The physical property temporal change prediction device 1 in the first to 13th embodiments and the modification that can be shaped in a card may include a card body. For example, the card body has shape and size that allow the card body to be used as a credit card, a cash card, or a security card. When the physical property temporal change prediction device 1 is a card body, using the property of the time-dependent element 40 undergoing phase transition that develops with time after production without supply of power or energy can provide expiration date for the card body. In the card body composed of the physical property temporal change prediction device 1, phase transition develops with time after production of the time-dependent phase transition material. The expiration date of the card body can be set according to the progress of phase transition of the card body by using a device capable of reading a change in physical property according to the progress of the phase transition of the card body as a device reading information of the card body. For example, the card boy composed of the physical property temporal change prediction device 1 can be configured to respond during a certain period of time but not respond after the period. The card body composed of the physical property temporal change prediction device 1 is suitably used as a credit card, a cash card, a security card, or the like in the light of security.

### EXAMPLES

Hereinafter, the embodiments are further described in more detail through Examples but are not limited to Examples.

### Example 1

The physical property temporal change prediction device 1A composed of the time-dependent element 40A (illustrated in FIG. 1) was prepared.

### (Preparation of Time-dependent Phase Transition Trititanium Pentoxide)

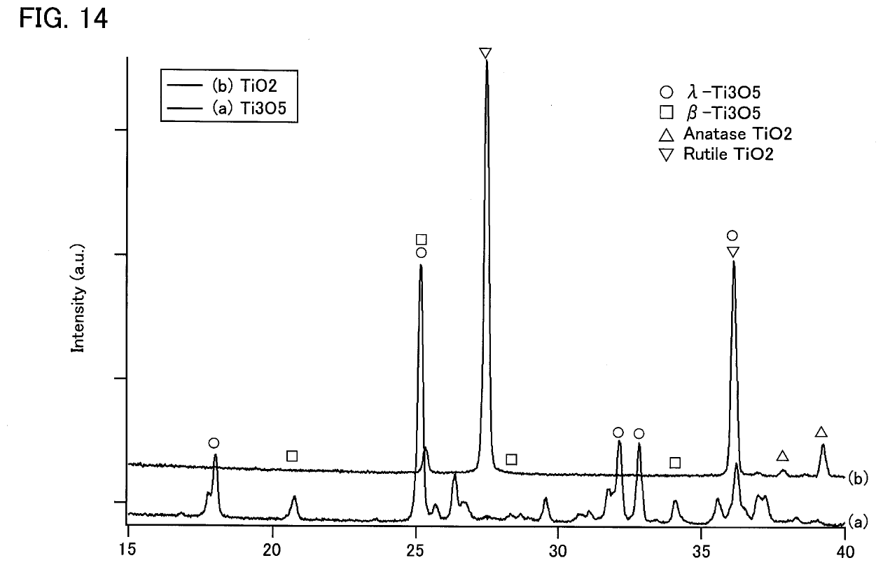

First, TiO₂ including rutile and anatase was prepared as the raw material. The result of X-ray diffraction for the prepared TiO₂ is illustrated in (b) of FIG. 14. Next, the TiO₂ was baked at 1140° C. for two hours in hydrogen gas atmosphere to form Ti₃O₅ powder. The result of X-ray diffraction for the obtained Ti₃O₅ powder is illustrated in (a) of FIG. 14. The result of X-ray diffraction in (a) of FIG. 14 has revealed that each powder sample of the obtained Ti₃O₅ powder included a mixture of λ-phase Ti₃O₅ and β-phase Ti₃O₅.

The result of a temporal change test described later revealed that as the elapsed time increased after production, the composition ratio of λ-phase Ti₃O₅ decreased while the composition ratio of β-phase Ti₃O₅ increased. The obtained Ti₃O₅ powder was therefore found to be the time-dependent phase transition trititanium pentoxide.

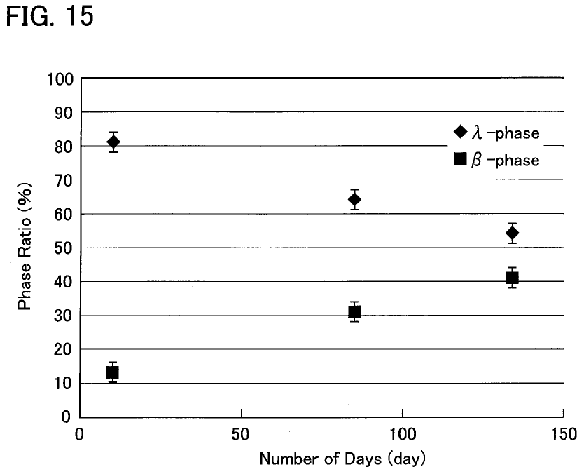

In the time-dependent phase transition trititanium pentoxide powder 10 days after production, the phase ratio of λ-phase trititanium pentoxide was 82 mol %; the phase ratio of β-phase trititanium pentoxide was 13 mol %; and the average grain size (median diameter) of crystal grains was 390 nm. The phase ratios of λ-phase trititanium pentoxide (λ-Ti₃O₅) and β-phase trititanium pentoxide (β-Ti₃O₅) were calculated based on the X-ray diffraction pattern measured with an X-ray diffractometer (by Rigaku Corporation). Next, some samples of time-dependent phase transition trititanium pentoxide powder were left at 25° C. and one atmosphere in air. The phase ratios of the λ-phase trititanium pentoxide and β-phase trititanium pentoxide were calculated for molded bodies of time-dependent phase transition trititanium pentoxide powder in which a predetermined number of days were passed, in the same manner as described above. The phase ratios of λ-phase trititanium pentoxide and β-phase trititanium pentoxide were measured in the time-dependent phase transition trititanium pentoxide powder samples several hours after production. The results thereof are illustrated in FIG. 15. FIG. 15 is a graph illustrating the relationship between elapsed time from production of time-dependent phase transition trititanium pentoxide and the phase ratio (λ-phase content) of λ-Ti₃O₅ and the phase ratio (β-phase content) of β-Ti₃O₅ in the time-dependent phase transition trititanium pentoxide several hours after production. The unit of the λ-phase content and β-phase content is mol %.

FIG. 15 has revealed that, with an increase in elapsed time from production, the phase ratio of λ-phase trititanium pentoxide exhibits a monotonically decreasing curve while the phase ratio of β-phase trititanium pentoxide exhibits a monotonically increasing curve.

The entire contents of Japanese Patent Application Publication No. 2017-068232 (filed on: 30 Mar. 2017) are incorporated by reference herein.

The embodiments are described through Examples. However, it should be obvious to those skilled in the art that the embodiments are not limited to these descriptions and various modifications and improvements can be made for the embodiments.

### INDUSTRIAL APPLICABILITY

According to the present invention, it is possible to provide a time-dependent element which includes a material that undergoes phase transition that develops with time without supply of power or energy. According to the present invention, moreover, it is possible to provide a physical property temporal change prediction device that predicts temporal changes in physical property with time by using the time-dependent element and an electric circuit breaker using the physical property temporal change prediction device.

### REFERENCE SIGNS LIST

1, 1A, 1B, 1C, 1D, 1E, 1F, 1G, 1H, 1I, 1J, 1K, 1L, 1M PHYSICAL PROPERTY TIME-DEPENDENT PREDICTION DEVICE
10, 10A, 10B, 10C, 10D, 10E, 10F, 10G, 10H, 10I, 10J, 10K, 10L, 10M PHYSICAL PROPERTY TIME-DEPENDENT PREDICTION DEVICE BODY
30, 30C, 30D, 30E, 30F, 30G, 30H, 30I, 30J BASE MATERIAL
40, 40A, 40B, 40C, 40D, 40E, 40F, 40G, 40H, 40I, 40J TIME-DEPENDENT ELEMENT
45 TIME-DEPENDENT PHASE TRANSITION TRITITANIUM PENTOXIDE-PARTICLE-CONNECTED BODY
50 SUBSTRATE
60 CONTAINER
70, 70a, 70b, 70c, 70d, 70e, 70f ELECTRODE

1. A time-dependent element, comprising
a time-dependent phase transition material that undergoes solid-solid phase transition developing with time after production irrespective of the presence of an external stimulus, wherein
one or more physical properties of the time-dependent element selected from a group consisting of composition, volume, transmittance, reflectance, electric resistance, and magnetic property change with time; and
the time-dependent phase transition material is composed of trititanium pentoxide including crystal grains of at least λ-phase trititanium pentoxide (λ-Ti₃O₅).

2-9. (canceled)

10. The time-dependent element according to claim 1, wherein
the time-dependent phase transition material is composed of trititanium pentoxide including crystal grains of λ-phase trititanium pentoxide (λ-Ti₃O₅) and β-phase trititanium pentoxide (β-Ti₃O₅).

11. The time-dependent element according to claim 1, wherein
the time-dependent phase transition material includes crystal grains of β-phase trititanium pentoxide (β-Ti₃O₅) and λ-phase trititanium pentoxide (λ-Ti₃O₅) at lower than 350° C. and has the property that at least a portion of crystal grains of β-phase trititanium pentoxide (β-Ti₃O₅) and λ-phase trititanium pentoxide (λ-Ti₃O₅) change into crystal grains of titanium dioxide (TiO₂) when the time-dependent phase transition material is heated to 350° C. or higher.

12. A physical property temporal change prediction device, comprising a physical property temporal change prediction device body including a time-dependent element according to claim 1, wherein
the physical property temporal change prediction device predicts a temporal change in one or more physical properties selected from a group consisting of composition, volume, transmittance, reflectance, electric resistance, and magnetic property.

13. The physical property temporal change prediction device according to claim 1, wherein the physical property temporal change prediction device is composed of a card body.

14. An electric circuit breaker, comprising a physical property temporal change prediction device according to claim 1, wherein
the electric circuit breaker predicts a temporal change in the electric resistance.

15. An electric circuit breaker, comprising a physical property temporal change prediction device according to claim 1, wherein
the electric circuit breaker predicts a temporal change in the volume.
